(19) United States
(12) Patent Application Publication
(10) Pub. No.: US 2024/0387387 A1
(43) Pub. Date: Nov. 21, 2024

(54) ELECTRONIC DEVICE AND METHOD FOR MANUFACTURING ELECTRONIC DEVICE

(71) Applicant: InnoLux Corporation, Miao-Li County (TW)

(72) Inventors: Jia-Yuan CHEN, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 18/633,534

(22) Filed: Apr. 12, 2024

(30) Foreign Application Priority Data
May 16, 2023 (CN) 202310547779.8

(51) Int. Cl. H01L 23/538; H01L 21/48; H01L 21/56; H01L 23/00; H01L 23/31; H01L 25/065; H01L 25/075; H01L 25/16; H01L 33/54; H01L 33/62

(52) U.S. Cl. CPC H01L 23/5383; H01L 21/4857; H01L 21/561; H01L 23/3121; H01L 24/19; H01L 24/20; H01L 24/32; H01L 24/83; H01L 24/96; H01L 24/97; H01L 33/62; H01L 25/0655; H01L 25/0753; H01L 25/16; H01L 25/162; H01L 25/167; H01L 33/54; H01L 2224/19; H01L 2224/211; H01L 2224/32225; H01L 2224/83192; H01L 2224/96; H01L 2224/97

(57) ABSTRACT

An electronic device and a manufacturing thereof are disclosed. The electronic device includes a first conductive layer, a first insulating layer, a second insulating layer, a second conductive layer, a plurality of semiconductor elements and a covering layer. The first insulating layer is disposed on the first conductive layer. In a cross-sectional view of the electronic device, the first insulating layer has two side-surfaces which are opposite to each other. The second insulating layer is disposed on the first insulating layer and in contact with the two side-surfaces of the first insulating layer. The second conductive layer is disposed on the second insulating layer and electrically connected to the first conductive layer. The plurality of semiconductor elements are disposed on the second conductive layer and electrically connected to the second conductive layer. The covering layer is disposed on the plurality of semiconductor elements.

### BACKGROUND OF THE DISCLOSURE

### 1. Field of the Disclosure

The present disclosure relates to an electronic device and a method for manufacturing an electronic device, and more particularly to an electronic device having a specific insulating layer structure and a manufacturing method thereof.

### 2. Description of the Prior Art

In recent years, due to the miniaturization and high density of electronic elements in electronic devices, various packaging technologies of electronic elements have been developed for integrating electronic elements. In the prior art, an electronic element may be disposed on multi-layered insulating layers, but the design of the multi-layered insulating layers in an electronic device may affect the product yield. For example, it takes more time to form holes in the insulating layers or cut the insulating layers when the thickness of the multi-layered insulating layers is thick, or the product yield may be affected when the whole structure of the electronic device is cut. In addition, the edge of the structure at the position being cut is also affected by moisture easily, resulting in decreasing of the product yield.

### SUMMARY OF THE DISCLOSURE

One of objectives of the present disclosure is to provide an electronic device and a method for manufacturing an electronic device, so as to solve the problems encountered by the conventional electronic devices and the manufacturing methods thereof. Through the structure and the manufacturing process of designing a second insulating layer in contact with a side-surface of a first insulating layer, the product yield may be improved, thereby improving the reliability of the electronic device.

The present disclosure provides an electronic device, which includes a first conductive layer, a first insulating layer, a second insulating layer, a second conductive layer, a plurality of semiconductor elements and a covering layer. The first insulating layer is disposed on the first conductive layer. In a cross-sectional view of the electronic device, the first insulating layer has two side-surfaces which are opposite to each other. The second insulating layer is disposed on the first insulating layer and in contact with the two side-surfaces of the first insulating layer. The second conductive layer is disposed on the second insulating layer and electrically connected to the first conductive layer. The plurality of semiconductor elements are disposed on the second conductive layer and electrically connected to the second conductive layer. The covering layer is disposed on the plurality of semiconductor elements.

The present disclosure further provides a method for manufacturing an electronic device, which includes: providing a substrate; forming a first insulating layer on the substrate; patterning the first insulating layer to form a first through-hole, wherein in a cross-sectional view of the electronic device, the first insulating layer has a side-surface corresponding to the first through-hole; forming a second insulating layer on the first insulating layer, wherein the second insulating layer contacts the side-surface of the first insulating layer; forming a conductive layer on the second insulating layer; arranging a plurality of semiconductor elements on the conductive layer and electrically connected to the conductive layer; and arranging a covering layer on the plurality of semiconductor elements.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional schematic diagram of an electronic device according to a first embodiment of the present disclosure.

FIG. 2 is a cross-sectional schematic diagram of an electronic device according to a second embodiment of the present disclosure.

FIG. 3 is a flowchart of a method for manufacturing an electronic device according to an embodiment of the present disclosure.

FIG. 4A to FIG. 4M are schematic diagrams illustrating the process of a method for manufacturing an electronic device of a first embodiment of the present disclosure.

FIG. 4N is a schematic diagram illustrating a portion of the process of a method for manufacturing an electronic device of a second embodiment of the present disclosure.

FIG. 5 is a cross-sectional schematic diagram of an electronic device according to a third embodiment of the present disclosure.

FIG. 6A to FIG. 6L are schematic diagrams illustrating the process of a method for manufacturing an electronic device of a third embodiment of the present disclosure.

FIG. 7 is a cross-sectional schematic diagram of an electronic device according to a fourth embodiment of the present disclosure.

FIG. 8A to FIG. 8K are schematic diagrams illustrating the process of a method for manufacturing an electronic device of a fourth embodiment of the present disclosure.

FIG. 9 is a top-view schematic diagram of embodiments of semiconductor elements and a shielding layer according to an electronic device of the present disclosure.

FIG. 10A and FIG. 10B are cross-sectional schematic diagrams of various embodiments of an electronic device of the present disclosure.

FIG. 11A and FIG. 11B are cross-sectional schematic diagrams of further embodiments of an electronic device of the present disclosure.

FIG. 12 is a cross-sectional schematic diagram of an embodiment that an electronic device of the present disclosure is bonded to another device.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in this document, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” mentioned in this document generally mean being within 20% of a given value or range, or being within 10%, 5%, 3%, 2%, 1% or 0.5% of a given value or range.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may be applied to a semiconductor package device, a display device, a light emitting device, a backlight device, an antenna device, a sensing device or a tiled device, but not limited herein. The electronic device may include a bendable or flexible electronic device. The display device may include a non-self-emissive display device or a self-emissive display device. The antenna device may include a liquid-crystal type antenna device or an antenna device other than liquid-crystal type, and the sensing device may include a sensing device used for sensing capacitance, light, heat or ultrasonic waves, but not limited herein. The electronic device may include electronic elements, and the electronic elements may include semiconductor elements. The semiconductor elements may include, for example, passive elements and active elements, such as capacitors, resistors, inductors, diodes, transistors, integrated circuits, etc. The diode may include a light emitting diode, a photodiode or a varicap diode. The light emitting diode may include, for example, an organic light emitting diode (OLED), a mini light emitting diode (mini LED), a micro light emitting diode (micro LED) or a quantum dot light emitting diode (quantum dot LED), but not limited herein. The tiled device may include, for example, a display tiled device or an antenna tiled device, but not limited herein. The semiconductor element may include a semiconductor layer or an electronic element manufactured by a semiconductor process, but not limited herein. It should be noted that the electronic device may be any arrangement and combination of the above, but not limited herein.

It should be noted that the technical features in different embodiments described in the following can be replaced, recombined, or mixed with one another to constitute another embodiment without departing from the spirit of the present disclosure.

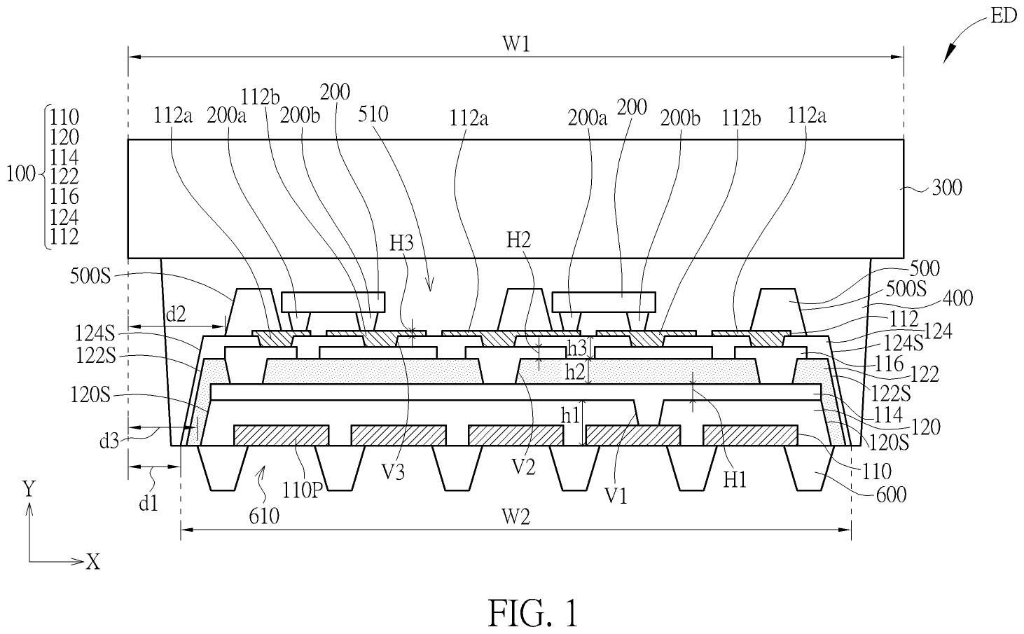

Please refer to FIG. 1, which is a cross-sectional schematic diagram of an electronic device according to a first embodiment of the present disclosure, wherein the electronic device ED shown in FIG. 1 may be manufactured by an RDL-first process. As shown in FIG. 1, an electronic device ED may include a circuit layer 100, a plurality of semiconductor elements 200 and a covering layer 300. The plurality of semiconductor elements 200 may be electrically connected to the circuit layer 100 respectively, wherein the circuit layer 100 may include a plurality of conductive layers and a plurality of insulating layers stacked in a direction Y. Specifically, the circuit layer 100 may include a conductive layer 110 (referred to as a first conductive layer), an insulating layer 120 (referred to as first insulating layer), an insulating layer 122 (referred to as a second insulating layer), and an conductive layer 112 (referred to as a second conductive layer). The conductive layer 110 may, for example, include a plurality of conductive pads 110P for electrically connecting with other electronic elements. The insulating layer 120 is disposed on the conductive layer 110, and in the cross-sectional view of the electronic device ED, the insulating layer 120 has two side-surfaces 120S which are opposite to each other (which may be regarded as being disposed contrary to each other), such as the surfaces at the left and right sides of the insulating layer 120 which are opposite to each other in a direction X in FIG. 1. The insulating layer 122 is disposed on the insulating layer 120 and in contact with the two side-surfaces 120S of the insulating layer 120, that is, the insulating layer 122 may contact and cover the two side-surfaces 120S of the insulating layer 120. In some embodiments, the insulating layer 122 may contact and cover two or more side-surfaces 120S of the insulating layer 120. That is to say, addition to that the insulating layer 122 contacts the two side-surfaces 120S of the insulating layer 120 in the cross-sectional view shown in FIG. 1, the insulating layer 122 may further contact other two side-surfaces of the insulating layer 120 in another cross-sectional direction different from the cross-sectional direction of FIG. 1, but not limited herein. The conductive layer 112 is disposed on the insulating layer 122 and electrically connected to the conductive layer 110. As shown in FIG. 1, the direction Y may be a normal direction of the electronic device ED, that is, opposite to a top-view direction of the electronic device ED, and the direction X may be parallel to a horizontal direction and perpendicular to the normal direction of the electronic device ED, such as parallel to an upper surface of the semiconductor element 200, but not limited herein.

As shown in FIG. 1, the conductive layer 110 may be the lowest conductive layer in the circuit layer 100, the conductive layer 112 may be the uppermost conductive layer in the circuit layer 100, and the circuit layer 100 may further include at least one conductive layer and at least one insulating layer between the conductive layer 110 and the conductive layer 112, so as to redistribute the circuit. For example, through the wire-distribution process, the contact positions of the wirings may be changed, the wirings may be integrated/merged, and/or the fan-out area of the wiring may be increased, but not limited herein. Therefore, the circuit layer 100 may be a redistribution layer (RDL), but the number of insulating layers and conductive layers in the circuit layer 100 and the circuit layout are not limited to the drawings provided by the present disclosure.

According to the embodiment shown in FIG. 1, the circuit layer 100 may include the conductive layer 110, the insulating layer 120, a conductive layer 114, the insulating layer 122, a conductive layer 116, an insulating layer 124 and the conductive layer 112 stacked in the direction Y in sequence. The insulating layer 120 may be disposed on the conductive layer 110, and the conductive layer 114 may be disposed on the insulating layer 120 and electrically connected to the conductive layer 110 though a connection hole V1 in the insulating layer 120. The insulating layer 122 may be disposed on the conductive layer 114 and the insulating layer 120, and in the cross-sectional view of the electronic device ED, the insulating layer 122 has two side-surfaces 122S which are opposite to each other, such as the surfaces at the left and right sides of the insulating layer 122 which are opposite to each other in the direction X in FIG. 1. The conductive layer 116 may be disposed on the insulating layer 122 and electrically connected to the conductive layer 114 through a connection hole V2 in the insulating layer 122. The insulating layer 124 may be disposed on the conductive layer 116 and the insulating layer 122, and the insulating layer 124 is in contact with the two side-surfaces 122S of the insulating layer 122, that is, the insulating layer 124 may contact and cover the two side-surfaces 122S of the insulating layer 122. In some embodiments, the insulating layer 124 may contact and cover two or more side-surfaces 122S of the insulating layer 122. That is to say, addition to that the insulating layer 124 contacts the two side-surfaces 122S of the insulating layer 122 in the cross-sectional view shown in FIG. 1, the insulating layer 124 may further contact other two side-surfaces of the insulating layer 122 in another cross-sectional direction different from the cross-sectional direction of FIG. 1, but not limited herein. In the cross-sectional view of the electronic device ED, the insulating layer 124 has two side-surfaces 124S which are opposite to each other, such as the surfaces at the left and right sides of the insulating layer 124 which are opposite to each other in the direction X in FIG. 1. In the direction X, one side-surface 122S of the insulating layer 122 may be located between the side-surface 120S of the insulating layer 120 and the side surface 124S of the insulating layer 124 which are corresponding and adjacent thereto. The conductive layer 112 may be disposed on the insulating layer 124 and electrically connected to the conductive layer 116 through a connection hole V3 in the insulating layer 124.

The conductive layers (such as the conductive layer 110, conductive layer 112, conductive layer 114 and conductive layer 116) in the circuit layer 100 may include, but are not limited to, metal materials such as titanium, copper, aluminum, tin, nickel, gold or silver or other suitable conductive materials. The insulating layers (such as the insulating layer 120, insulating layer 122 and insulating layer 124) in the circuit layer 100 may include, but are not limited to, polyimide (PI), photosensitive polyimide (PSPI), photopolymer, modified polyimide (MPI) or other suitable materials. A thickness of each insulating layer may range from 2 micrometers (μm) to 6 micrometers. In some embodiments, the insulating layer may include inorganic materials, including silicon nitride (SiNx), silicon oxide (SiOx), silicon oxynitride (SiOxNy) or other suitable materials, and a thickness thereof may range from 0.05 micrometers to 1 micrometer, but not limited herein. The connection holes (such as the connection hole V1, connection hole V2 and connection hole V3) in each insulating layer may be formed by a photolithography process, for example, but not limited herein.

According to the structural design of the circuit layer 100 described above, the insulating layer 122 located at the upper layer, compared with the insulating layer 120, may extend to cover the side-surfaces 120S of the insulating layer 120 located at the lower layer, and the insulating layer 124 located at the upper layer compared with the insulating layer 122 may extend to cover the side-surfaces 122S of the insulating layer 122 located at the lower layer. That is to say, the upper insulating layer (which may be referred to as the second insulating layer) may cover the edge of the lower insulating layer (which may be referred to as the first insulating layer). The above structural design may provide a better protection effect, such as reducing the influence of moisture, and further improve the reliability of the electronic device ED.

In some embodiments, as shown in FIG. 1, a thickness H1 of a portion of the conductive layer 114 located above the upper surface of the insulating layer 120 may be greater than a thickness H2 of a portion of the conductive layer 116 located above the upper surface of the insulating layer 122, and the thickness H2 may be greater than a thickness H3 of a portion of the conductive layer 112 located above the upper surface of the insulating layer 124 (i.e., H1>H2>H3). That is to say, the conductive layer closer to the conductive layer 110 may have a greater thickness, so as to mitigate the problems such as loading increase or signal distortion caused by integrating and merging the wirings, thereby improving the stability of signal transmission. The term “thickness” mentioned in the present disclosure may mean the maximum thickness measured from one end to another end of a layer or element along the direction Y in a cross-sectional view. In some embodiments, a thickness h1 of the insulating layer 120 may be greater than a thickness h2 of a portion of the insulating layer 122 located above the upper surface of the insulating layer 120, and the thickness h2 may be greater than a thickness h3 of a portion of the insulating layer 124 located above the upper surface of the insulating layer 122 (i.e., h1>h2>h3), so as to mitigate the coupling problem or signal interference resulted from signal becoming large, thereby improving the stability of signal transmission. In some embodiments, a ratio of the thickness h1 to the thickness H1, a ratio of the thickness h2 to the thickness H2 and a ratio of thickness h3 to the thickness H3 may range from 1 to 3 respectively, so that the coupling problem between wirings may be mitigated.

The plurality of semiconductor elements 200 are disposed on the conductive layer 112 and electrically connected to the conductive layer 112, that is, the plurality of semiconductor elements 200 may be respectively disposed on the conductive layer 112 located at the uppermost layer in the circuit layer 100. Each of the semiconductor elements 200 may include a first electrode 200a and a second electrode 200b. The first electrode 200a may be electrically connected to the conductive layer 112. For example, the first electrode 200a may be electrically connected to the conductive layer 110 through the conductive layer 112, the conductive layer 116 and the conductive layer 114. The second electrode 200b may also be electrically connected to one or more of the conductive layer 112, the conductive layer 116, the conductive layer 114 and the conductive layer 110. For example, the second electrode 200b may be electrically connected to other circuits through the conductive layer 112 and the conductive layer 116, but not limited herein. The plurality of semiconductor elements 200 may include at least one of light emitting elements, integrated circuit chips, and passive components. The light emitting element may be a die or a chip, such as including a light emitting diode die or a light emitting diode chip, but not limited herein. One of the plurality of semiconductor elements 200 may be different from another one of the plurality of semiconductor elements 200 in function. For example, one of the semiconductor elements 200 may provide a function of emitting light, and another one of the semiconductor elements 200 may provide a function of receiving light, but not limited herein. The functions of the semiconductor elements 200 may include, for example, emitting light, receiving light, controlling circuits and/or adjusting electromagnetic waves, but not limited herein.

The covering layer 300 is disposed on the plurality of semiconductor elements 200. In the cross-sectional view of the electronic device ED, a width W1 of the covering layer 300 may be greater than a width W2 of the circuit layer 100, that is, the width W1 of the covering layer 300 may be greater than a width of the insulating layer 124. The term “width” mentioned in the present disclosure may mean the maximum length measured from one end to another end of a layer or element along the direction X in a cross-sectional view. In addition, in the direction X, a distance dl may exist between an edge of the cover layer 300 and a corresponding adjacent edge of the circuit layer 100 (or the insulating layer 124). The term “distance” mentioned in the present disclosure may mean the minimum length measured from one end to another end of a layer or element along the direction X in a cross-sectional view. The distance d1 may range from 0.1 millimeters (mm) to 0.4 millimeters, for example, but not limited herein. According to the embodiment shown in FIG. 1, the cover layer 300 may be a substrate, for example. The substrate may be a rigid substrate or a flexible substrate. For example, the rigid substrate may include glass, ceramics or sapphire, and the flexible substrate may include polyimide (PI), polycarbonate (PC), polyethylene terephthalate (PET) or poly (methyl methacrylate) (PMMA), but not limited herein.

According to the embodiment shown in FIG. 1, the electronic device ED may further include an adhesive layer 400 disposed between the covering layer 300 and the plurality of semiconductor elements 200. In the cross-sectional view of the electronic device ED, the adhesive layer 400 may contact the two side-surfaces 124S of the insulating layer 124, that is, the adhesive layer 400 covers the side-surfaces 124S of the insulating layer 124, which may improve the adhesion between the covering layer 300 and the circuit layer 100 and make the structure of the electronic device ED more stable. In some embodiments, the adhesive layer 400 may contact and cover two or more side-surfaces 124S of the insulating layer 124. That is to say, addition to that the adhesive layer 400 contacts the two side-surfaces 124S of the insulating layer 124 in the cross-sectional view shown in FIG. 1, the adhesive layer 400 may further contact other two side-surfaces of the insulating layer 124 in another cross-sectional direction different from the cross-sectional direction of FIG. 1, but not limited herein.

According to the embodiment shown in FIG. 1, the electronic device ED may further include a shielding layer 500 disposed between the covering layer 300 and the insulating layer 124. The shielding layer 500 may have a plurality of through-holes 510, and at least one of the plurality of semiconductor elements 200 may be disposed in one of the plurality of through-holes 510 respectively. As shown in FIG. 1, each of the semiconductor elements 200 may be disposed in one through-hole 510 respectively, but not limited herein. In a variant embodiment, two or more semiconductor elements 200 may be disposed in one through-hole 510. The shielding layer 500 may be disposed on the circuit layer 100, for example, on the insulating layer 124 and the conductive layer 112, and the through-holes 510 of the shielding layer 500 may expose a portion of the insulating layer 124 and a portion of the conductive layer 112. The term “through-hole” mentioned in the present disclosure may mean a hole or an opening which is communicated from top to bottom, that is, a portion of a layer or element located therebelow may be exposed by the through-hole, wherein the size thereof is not limited. The shielding layer 500 may reduce the mutual interference of the semiconductor elements 200 in the adjacent through-holes 510 during operation, such as (but not limited to) reducing the interference of light or signals. In some embodiments, the shielding layer 500 may serve as a light shielding layer when the semiconductor elements 200 are light emitting elements, and the material of the light shielding layer may include black photoresist material, organic material, opaque material, white material, gray material or other suitable materials, but not limited herein. In some embodiments, the shielding layer 500 may be a pixel definition layer (PDL), which is used to define pixel areas, the light emitting areas of the pixels and/or the range where the semiconductor elements 200 may be arranged. As shown in FIG. 1, the adhesive layer 400 of the electronic device ED may be disposed between the covering layer 300 and the shielding layer 500. In addition, in the cross-sectional view of the electronic device ED, the shielding layer 500 may have two outside-surfaces 500S, such as the two outermost (e.g., the leftmost and rightmost) surfaces of the shielding layer 500 in FIG. 1, and the adhesive layer 400 may contact the two side-surfaces 124S of the insulating layer 124 and the two outside-surfaces 500S of the shielding layer 500, so as to improve the adhesion between different layers in the whole structure and enable the whole structure to have better packaging reliability.

In some embodiments, as shown in FIG. 1, a size of each of the through-holes 510 of the shielding layer 500 is greater than a size of each of the semiconductor elements 200. Therefore, within the range of each through-hole 510, there may be a portion of the conductive layer 112 on which the semiconductor element 200 is not disposed, so the reserved space may be supplemented with another semiconductor element 200 when the originally disposed semiconductor element 200 is abnormal. In some embodiments, the shielding layer 500 is disposed on the conductive layer 112, and the conductive layer 112 may include a plurality of first conductive elements 112a and a plurality of second conductive elements 112b. Each of the first conductive elements 112a may be a common electrode, for example, electrically connected to the conductive layer 114 through the conductive layer 116, and at least one of the first conductive elements 112a may extend along the direction X and be overlapped with a portion of the shielding layer 500 in the direction Y, so that the first conductive element 112a is disposed within the range of two adjacent through-holes 510 (or two adjacent working areas) and may be commonly used by the semiconductor elements 200 correspondingly disposed in the two adjacent through-holes 510, thereby reducing the space occupied by the wiring. Each of the second conductive elements 112b may extend along the direction X but not cross the shielding layer 500 and be disposed within the range of one of the through-holes 510 of the shielding layer 500. For example, each of the second conductive elements 112b may be disposed in one of the through-holes 510 (or a working area) respectively. Taking the embodiment shown in FIG. 1 as an example, within the range of each through-hole 510 of the shielding layer 500, there may be two first conductive elements 112a and one second conductive element 112b, wherein the first conductive elements 112a may be configured to be electrically connected to the first electrode 200a of the semiconductor element 200, and the second conductive element 112b may be configured to be electrically connected to the second electrode 200b of the semiconductor element 200. Therefore, according to the above structural design, the supplementary semiconductor element 200 may be disposed on one of the first conductive elements 112a and the second conductive element 112b within the range of the corresponding through-hole 510, so as to repair the abnormality.

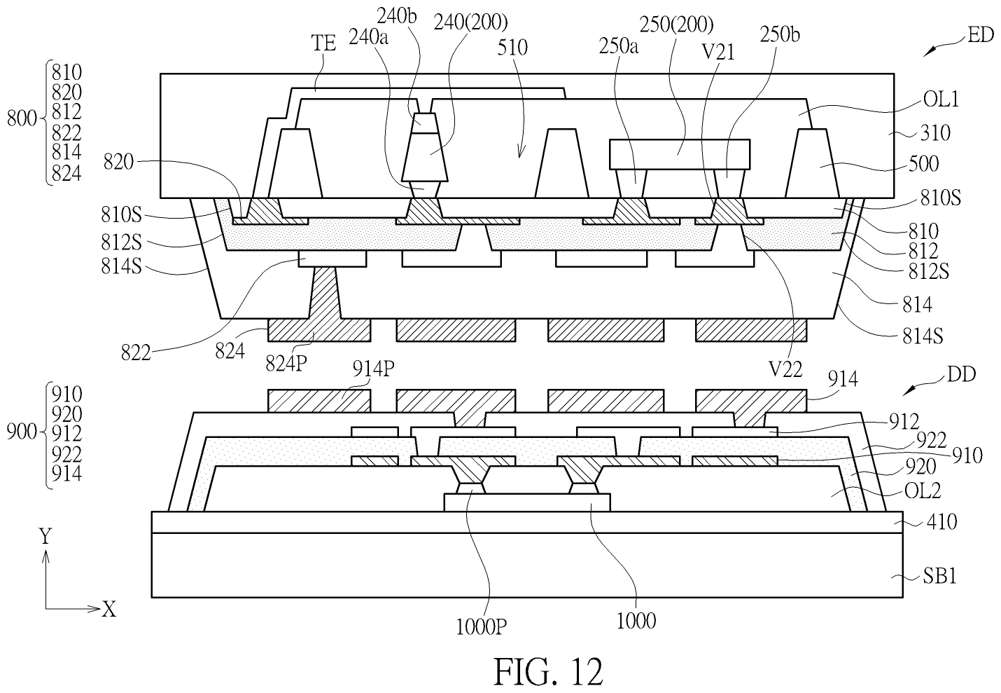

In some embodiments, as shown in FIG. 1, the electronic device ED may further optionally include an insulating layer 600 disposed on a side of the circuit layer 100 opposite to the semiconductor elements 200. The insulating layer 600 may have a plurality of through-holes 610, and each of the through-holes 610 may expose a portion of the surface of one of the conductive pads 110P of the conductive layer 110 to define a range where a connection element (not shown) may be arranged and electrically connected to the conductive pad 110P. The connection element may be a solder ball for example, which may be used for electrically connecting the conductive pad 110P with an external circuit or other electronic devices (for example (but not limited to), a device DD shown in FIG. 12). Therefore, by arranging the insulating layer 600, the connection elements formed subsequently can be effectively accommodated within the through-holes 610, and the probability of short circuit of adjacent connection elements may be reduced. In some embodiments, the insulating layer 600 may be trapezoidal with increasing width along the positive direction of the direction Y in the cross-sectional view, and a hydrophobicity treatment may be performed to the surface of the insulating layer 600, so that the connection elements may be more effectively arranged in the through-holes 610.

In some embodiments, as shown in FIG. 1, in the direction X, a distance d2 may exist between an edge of the covering layer 300 and a corresponding adjacent edge of the shielding layer 500, and a distance d3 may exist between the edge of the covering layer 300 and a corresponding adjacent edge of the insulating layer 600, wherein the distance d2 may be greater than the distance d3, and the distance d3 may be greater than the distance d1 (i.e., d2>d3>d1). For example, the distance d2 may range from 1 millimeter to 2 millimeters, and the distance d3 may range from 0.5 millimeters to 1 millimeter, but not limited herein. In order to reduce the element damage in the manufacturing process, the edge of the shielding layer 500 and the edge of the insulating layer 600 need to have a certain distance from the edge of the circuit layer 100, so that the distance d2 and the distance d3 are both greater than the distance d1. Furthermore, since the upper insulating layer extends to cover the side-surfaces of the lower insulating layer in the circuit layer 100, the circuit layer 100 may be generally trapezoidal with decreasing width along the positive direction of the direction Y in the cross-sectional view. The shielding layer 500 is disposed on the smaller upper surface of the circuit layer 100, and the insulating layer 600 is disposed on the larger lower surface of the circuit layer 100, so the distance d2 may be greater than the distance d3. In addition, through the structural design that the distance d3 is less than the distance d2, a distance between the two outermost surfaces (such as the leftmost surface and the rightmost surface) of the insulating layer 600 in the direction X may be greater than a distance between the two outside-surfaces 500S of the shielding layer 500, so that the structural stability may be improved and the structure may not be tilted easily, and therefore the electronic device ED may be connected to external circuits or other electronic devices more easily and stably.

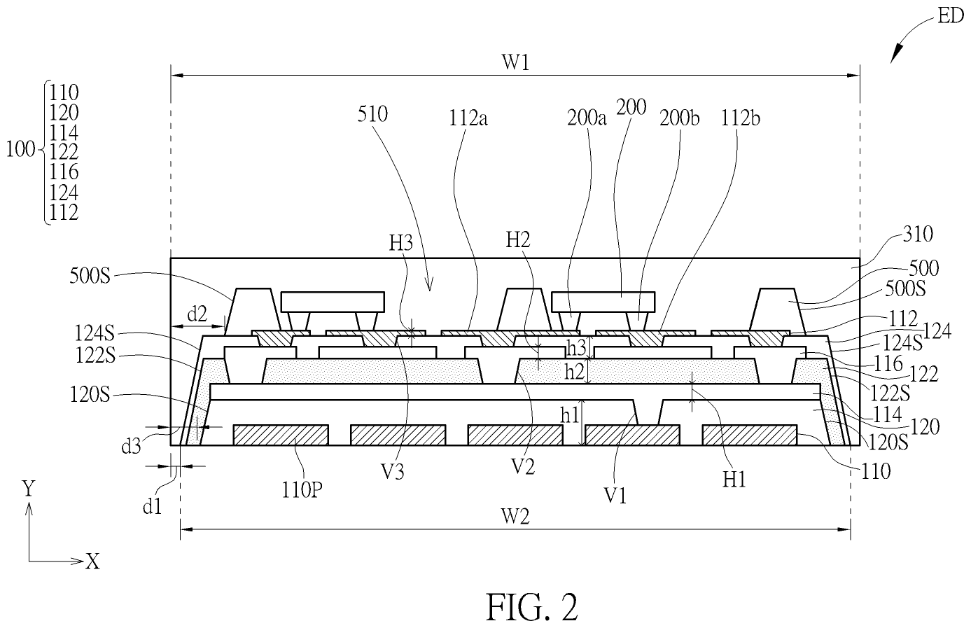

Please refer to FIG. 2, which is a cross-sectional schematic diagram of an electronic device according to a second embodiment of the present disclosure, wherein the electronic device ED shown in FIG. 2 may be manufactured by an RDL-first process. According to embodiment shown in FIG. 2, the covering layer 310 may be configured to encapsulate the plurality of semiconductor elements 200, that is, the covering layer 310 may be an encapsulation layer, for example. The encapsulation layer includes, for example, epoxy, ceramics, epoxy molding compound (EMC), other suitable materials or combinations of the above materials. A width W1 of the covering layer 310 may be greater than a width W2 of the circuit layer 100, that is, a distance d1 may exist between an edge of the covering layer 310 and an corresponding adjacent edge of the circuit layer 100 (or the insulating layer 124) in the direction X. In the cross-sectional view of the electronic device ED, the covering layer 310 may contact the two side-surfaces 124S of the insulating layer 124, that is, the covering layer 310 covers the side-surfaces 124S of the insulating layer 124 to provide a better protection effect. In some embodiments, as shown in FIG. 2, the covering layer 310 may be further configured to encapsulate the shielding layer 500. In the cross-sectional view of the electronic device ED, the shielding layer 500 may have two outside-surfaces 500S, such as the two outermost (e.g., the leftmost and rightmost) surfaces of the shielding layer 500 in FIG. 2, and the covering layer 310 may contact the two side-surfaces 124S of the insulating layer 124 and the two outside-surfaces 500S of the shielding layer 500, so as to provide a better protection effect and improve the adhesion between layers. The relative arrangement positions and materials of other elements and layers of the electronic device ED shown in FIG. 2 may refer to the related contents of the first embodiment of the present disclosure described above, which will not be described redundantly herein.

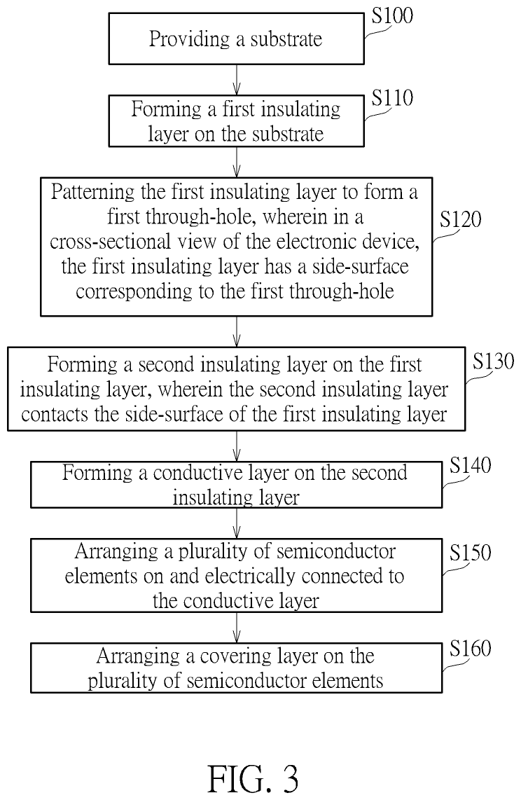

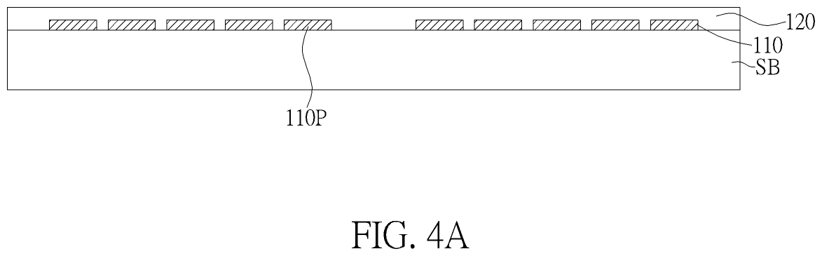

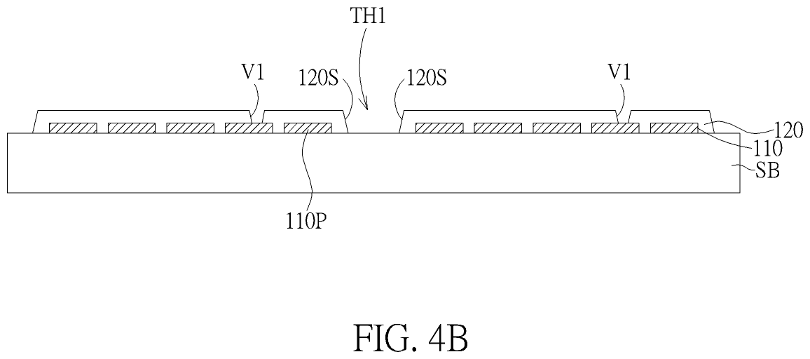

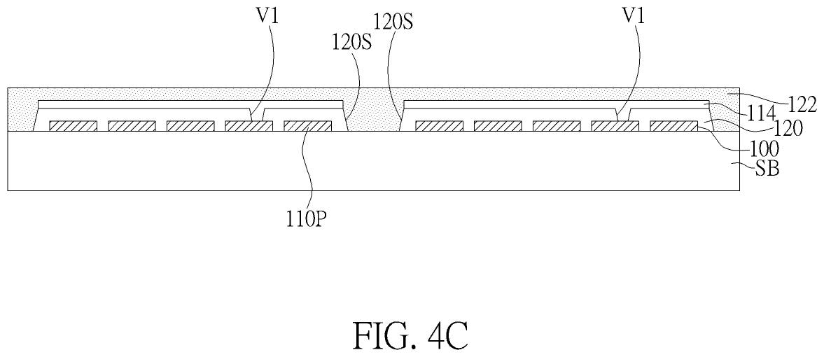

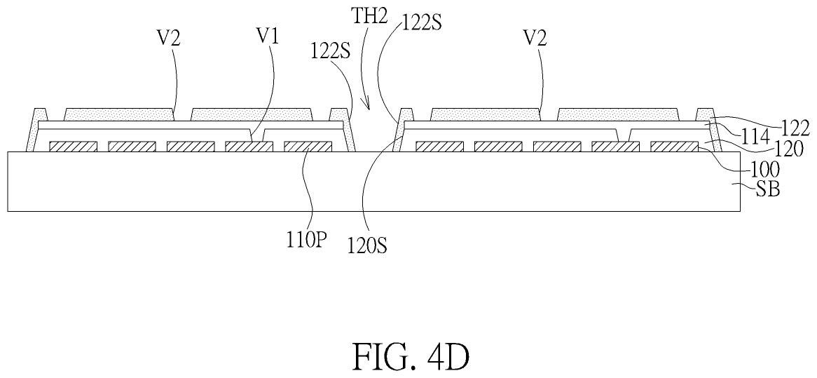

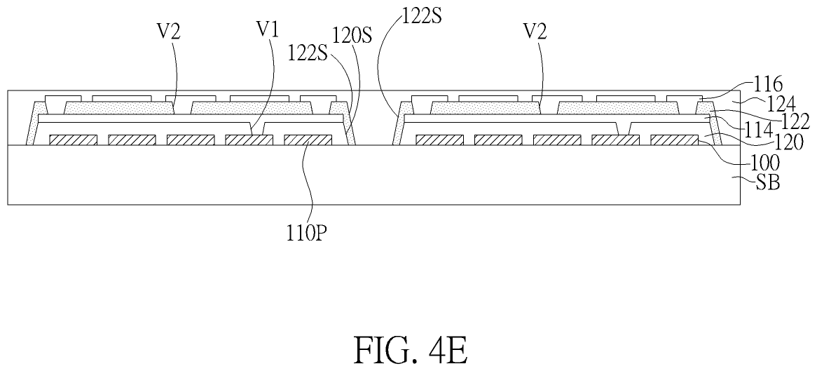

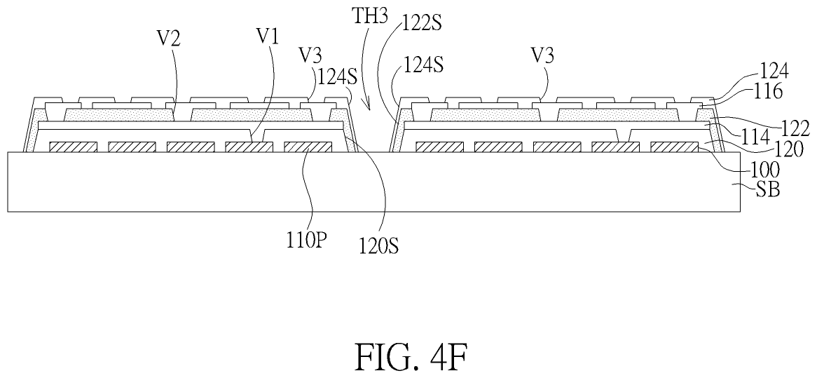

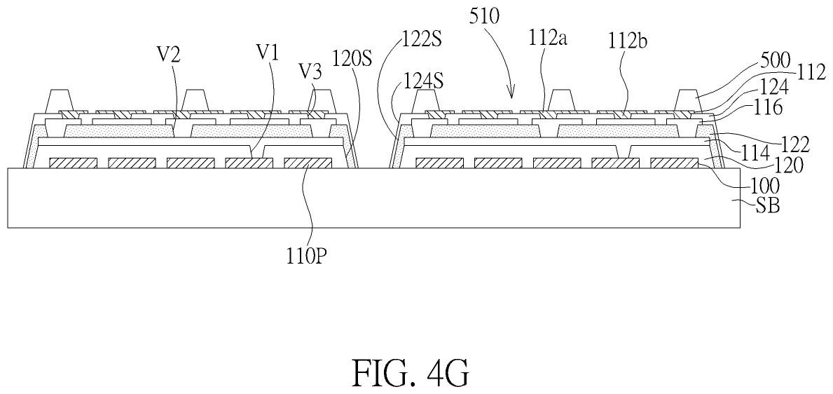

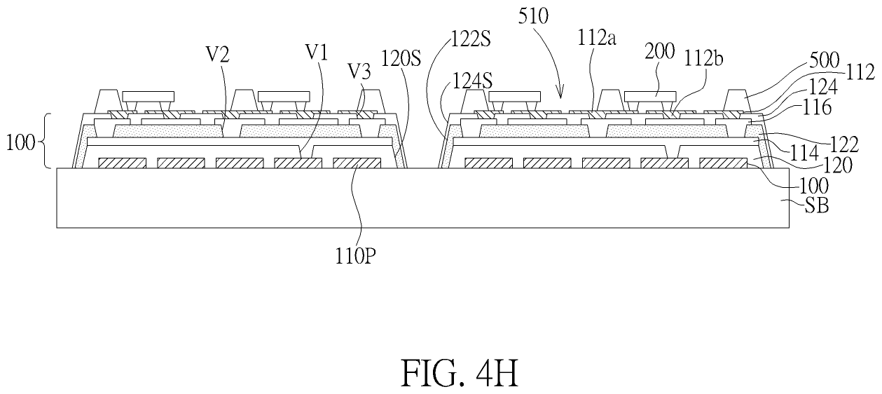

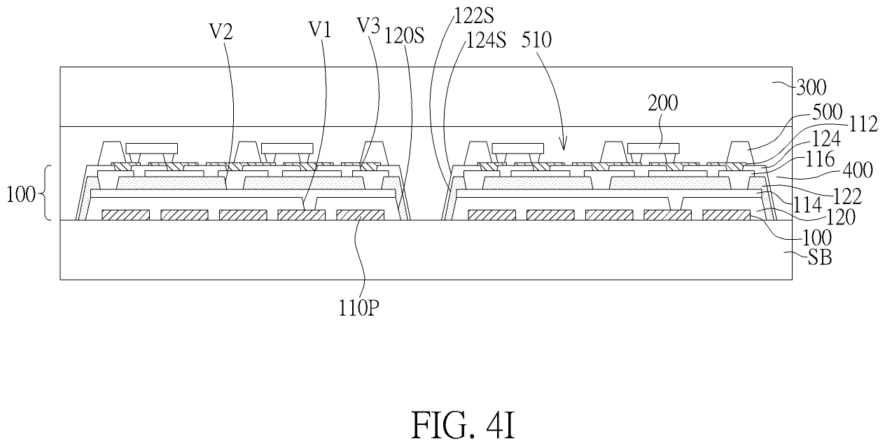

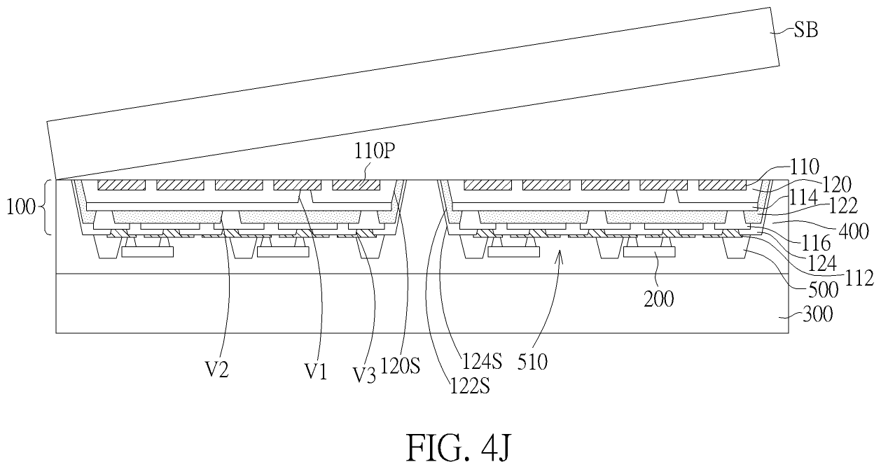

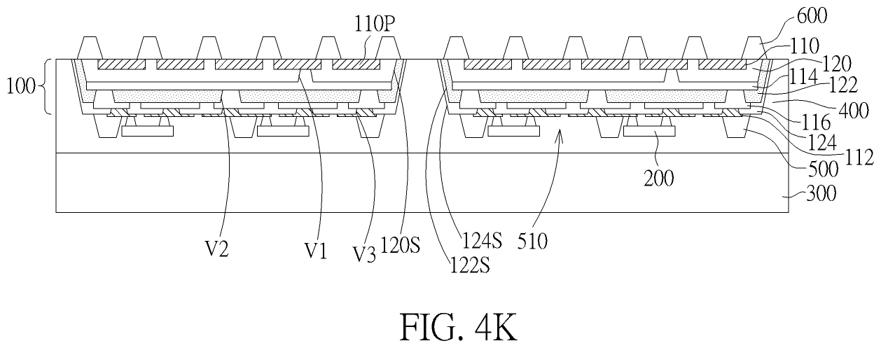

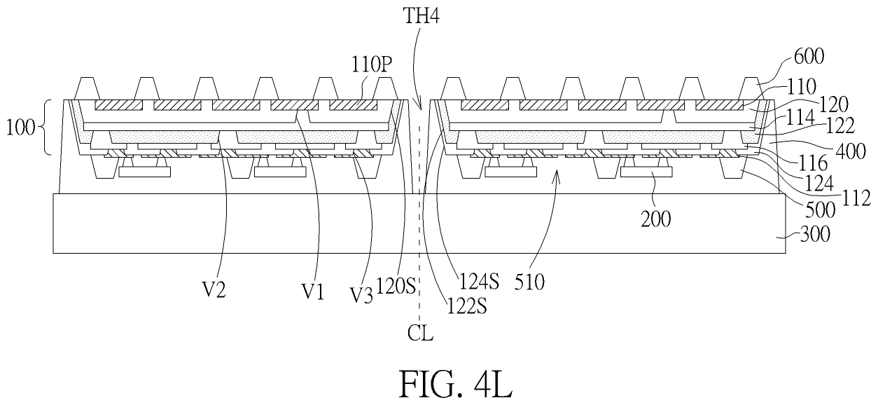

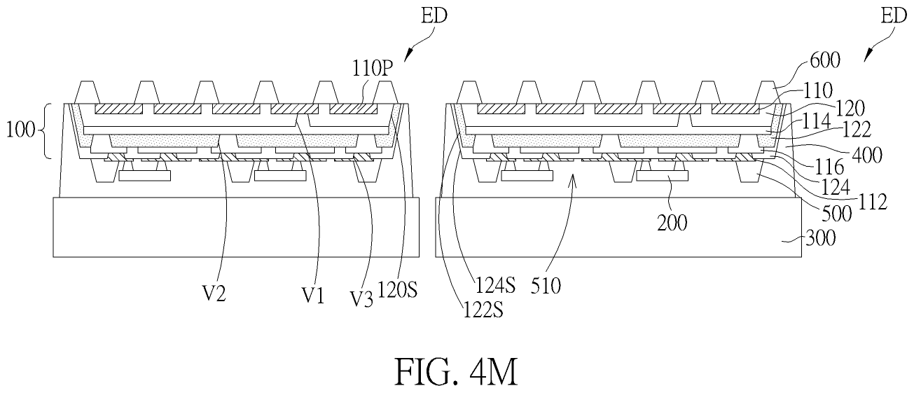

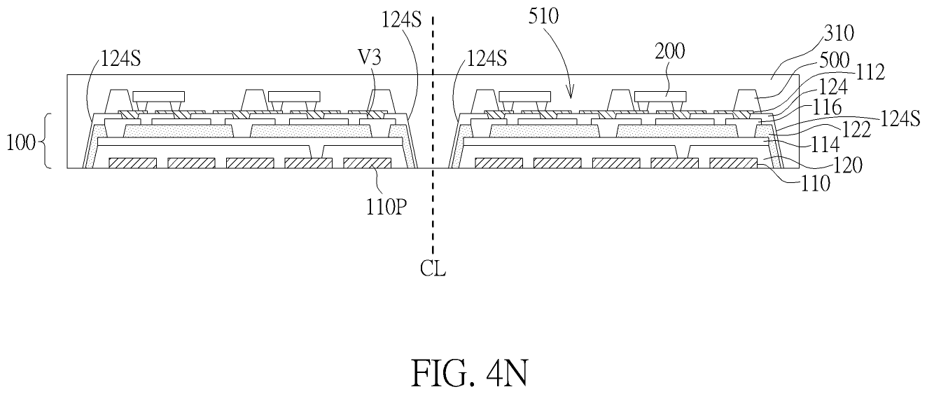

Please refer to FIG. 3 and FIG. 4A to FIG. 4M. FIG. 3 is a flowchart of a method for manufacturing an electronic device according to an embodiment of the present disclosure. FIG. 4A to FIG. 4M are schematic diagrams illustrating the process of a method for manufacturing an electronic device of a first embodiment of the present disclosure. As shown in FIG. 3, a method for manufacturing an electronic device ED according to an embodiment of the present disclosure may include steps as follows:
Step S100: providing a substrate;
Step S110: forming a first insulating layer on the substrate;
Step S120: patterning the first insulating layer to form a first through-hole, wherein, in a cross-sectional view of the electronic device, the first insulating layer has a side-surface corresponding to the first through-hole;
Step S130: forming a second insulating layer on the first insulating layer, wherein the second insulating layer contacts the side-surface of the first insulating layer;
Step S140: forming a conductive layer on the second insulating layer;
Step S150: arranging a plurality of semiconductor elements on the conductive layer and electrically connected to the conductive layer; and
Step S160: arranging a covering layer on the plurality of semiconductor elements.

Specifically, as shown in FIG. 4A, first, Step S100 is performed to provide a substrate SB. The patterned conductive layer 110 may be formed on the substrate SB, wherein the conductive layer 110 may include a plurality of conductive pads 110P. Then, Step S110 is performed to form an insulating layer 120 (referred to as a first insulating layer) on the substrate SB, and at this time, the conductive layer 110 may be located between the substrate SB and the insulating layer 120. Then, as shown in FIG. 4B, Step S120 is performed to pattern the insulating layer 120 to form a through-hole TH1 (referred to as a first through-hole) and a plurality of connection holes V1. Wherein, in the cross-sectional view of the process of the electronic device ED, the insulating layer 120 has a side-surface 120S corresponding to the through-hole TH1, and another through-hole may further exist at another side opposite to the side-surface 120S in this structure, so that the manufactured electronic device has a symmetrical structure. The side surface 120S of the insulating layer 120 may be adjacent to the through-hole TH1 or define the through hole TH1, that is, a side wall of the through-hole TH1 may be regarded as the side-surface 120S of the insulating layer 120. As shown in FIG. 4B, the through-hole TH1 passes through the insulating layer 120 to expose the substrate SB, and the connection holes V1 pass through the insulating layer 120 located on the conductive layer 110 to expose a portion of the conductive layer 110 below the insulating layer 120, such as exposing the corresponding conductive pads 110P. Through a photolithography process, the connection holes V1 and the through-hole TH1 may be formed in the insulating layer 120 at the same time, wherein forming the through-hole TH1 earlier in this step may effectively reduce the complexity of the structure within the through-hole TH1.

As shown in FIG. 4C, then, the patterned conductive layer 114 may be formed on the insulating layer 120, and the conductive layer 114 may be electrically connected to the conductive layer 110 through the connection holes V1. Then, Step S130 is performed to form an insulating layer 122 (referred to as a second insulating layer) on the insulating layer 120 and the conductive layer 114. Then, as shown in FIG. 4D, the insulating layer 122 may be patterned to form a through-hole TH2 (referred to as second through-hole) and a plurality of connection holes V2, wherein a size of the formed through-hole TH2 may be less than a size of the through-hole TH1 (that is, the minimum width of the through-hole TH2 is less than the minimum width of the through-hole TH1), so that the insulating layer 122 may contact the side-surface 120S of the insulating layer 120 after patterning the insulating layer 122. In the cross-sectional view of the process of the electronic device ED, the insulating layer 122 has a side-surface 122S corresponding to the through-hole TH2. The side surface 122S of the insulating layer 122 may be adjacent to the through-hole TH2 or define the through hole TH2, that is, a side wall of the through-hole TH2 may be regarded as the side-surface 122S of the insulating layer 122. As shown in FIG. 4D, the through-hole TH2 passes through the insulating layer 122 to expose the substrate SB, and the connection holes V2 pass through the insulating layer 122 located on the conductive layer 114 to expose a portion of the conductive layer 114 below the insulating layer 122.

As shown in FIG. 4E, then, the patterned conductive layer 116 may be formed on the insulating layer 122, and the conductive layer 116 may be electrically connected to the conductive layer 114 through the connection holes V2. Then, the insulating layer 124 is formed on the insulating layer 122 and the conductive layer 116. Then, as shown in FIG. 4F, the insulating layer 124 is patterned to form a through-hole TH3 and a plurality of connection holes V3, wherein a size of the formed through-hole TH3 may be less than the size of the through-hole TH2 (that is, the minimum width of the through-hole TH3 is less than the minimum width of the through-hole TH2), so that the insulating layer 124 may contact the side-surface 122S of the insulating layer 122 after patterning the insulating layer 124. In the cross-sectional view of the process of the electronic device ED, the insulating layer 124 has a side-surface 124S corresponding to the through-hole TH3. The side-surface 124S of the insulating layer 124 may be adjacent to the through-hole TH3 or define the through hole TH3, that is, a side wall of the through-hole TH3 may be regarded as the side-surface 124S of the insulating layer 124. As shown in FIG. 4F, the through-hole TH3 passes through the insulating layer 124 to expose the substrate SB, and the connection holes V3 pass through the insulating layer 124 located on the conductive layer 116 to expose a portion of the conductive layer 116 below the insulating layer 124.

As shown in FIG. 4G, Step S140 is performed to form the patterned conductive layer 112 on the insulating layer 124, and the conductive layer 112 may be electrically connected to the conductive layer 116 through the connection holes V3, wherein the conductive layer 112 may include a plurality of first conductive elements 112a and a plurality of second conductive elements 112b, such that the manufacturing of the circuit layer 100 may be completed. Then, the patterned shielding layer 500 may be formed on the insulating layer 124 and the conductive layer 112, wherein the shielding layer 500 may have a plurality of through-holes 510. Then, as shown in FIG. 4H, Step S150 is performed to arrange a plurality of semiconductor elements 200 on the conductive layer 112 and electrically connected to the conductive layer 112. For example, each of the semiconductor elements 200 may be transferred into one of the plurality of through-holes 510 and connected to the conductive layer 112. Then, as shown in FIG. 4I, Step S160 is performed to arrange the covering layer 300 on the plurality of semiconductor elements 200. The covering layer 300 is, for example (but not limited to), a substrate, and the substrate may be disposed on the circuit layer 100 and the semiconductor elements 200 through the adhesive layer 400 optionally. According to the method for manufacturing the electronic device ED of the present disclosure, the connection holes and the through-hole may be simultaneously formed in the insulating layer through the photolithography process during the manufacturing process, and the formed through-holes may correspond to a predetermined cutting position in the subsequent cutting process, but not limited herein. Therefore, through the method of forming the through-holes step by step and layer by layer, the complexity of the structure in the through-holes may be effectively reduced, and the subsequent cutting process may be completed more easily.

In some embodiments, as shown in FIG. 4I, the adhesive layer 400 may be further formed on the covering layer 300 before arranging the covering layer 300 on the plurality of semiconductor elements 200, so that the adhesive layer 400 is arranged between the covering layer 300 and the plurality of semiconductor elements 200 and can be used for adhering and fixing the covering layer 300. The adhesive layer 400 is formed by coating, for example, but not limited herein. In addition, as shown in FIG. 4J, after arranging the covering layer 300 on the plurality of semiconductor elements 200, the whole structure may be flipped upside down and the substrate SB is removed. Then, as shown in FIG. 4K, the insulating layer 600 may be optionally formed on the circuit layer 100, that is, the patterned insulating layer 600 may be formed on a side of the circuit layer 100 opposite to the semiconductor elements 200, wherein the insulating layer 600 may have a plurality of through-holes 610 to expose a portion of the surface of each conductive pad 110P. The insulating layer 600 may be disposed within a range not exceeding the edge of the circuit layer 100, so as to facilitate the subsequent cutting process.

Then, as shown in FIG. 4L, the adhesive layer 400 may be patterned to form a through-hole TH4 (referred to as a third through-hole) before cutting the covering layer 300, so as to expose the surface of the covering layer 300. For example, the through-hole TH4 may be formed through a laser cutting process or a development process. The position of the through-hole TH4 may correspond to the previous through-hole TH1. In some embodiments, a portion of the adhesive layer 400 close to the edge of the covering layer 300 may be removed at the same time when performing the step of patterning the adhesive layer 400, so that the opposite edges of the adhesive layer 400 may be more symmetrical after the adhesive layer 400 is patterned. Then, as shown in FIG. 4L and FIG. 4M, the covering layer 300 may be cut along the cutting path CL corresponding to the through-hole TH4, so as to obtain a plurality of electronic devices ED as shown in FIG. 1. For example, the covering layer 300 may be cut by a cutting-wheel cutting process or a laser cutting process. By patterning the adhesive layer 400 and cutting the covering layer 300 by different steps and different processes, it may be more easily to perform the cutting process for completing the manufacturing of the electronic device ED. As described above, the position of the through-hole TH4 (i.e., the corresponding positions of the through-hole TH1, the through-hole TH2, and the through-hole TH3) may correspond to the position of the cutting path.

Please refer to FIG. 4N, accompanied with FIG. 4A to FIG. 4H. FIG. 4N is a schematic diagram illustrating a portion of the process of a method for manufacturing an electronic device according to a second embodiment of the present disclosure, wherein FIG. 4N continues from FIG. 4H. In some embodiments, Step S160 is performed to arrange the covering layer 310 on the plurality of semiconductor elements 200, wherein the covering layer 310 may be, for example (but not limited to), an encapsulation layer configured to encapsulate the semiconductor elements 200. Furthermore, the covering layer 310 may contact the side-surface 124S of the insulating layer 124. Then, the substrate SB may be removed, and the covering layer 310 may be cut along the cutting path CL, so as to obtain a plurality of electronic devices ED as shown in FIG. 2. For example, the covering layer 310 may be cut by a cutting-wheel cutting process or a laser cutting process. The position of the cutting path CL may correspond to the positions of the above through-hole TH1, through-hole TH2, and through-hole TH3.

Some embodiments of the electronic devices and related manufacturing methods of the present disclosure will be detailed in the following. In order to simplify the illustration, the same elements in the following would be labeled with the same symbols. The differences between different embodiments are described in detail below, and the same features would not be described redundantly.

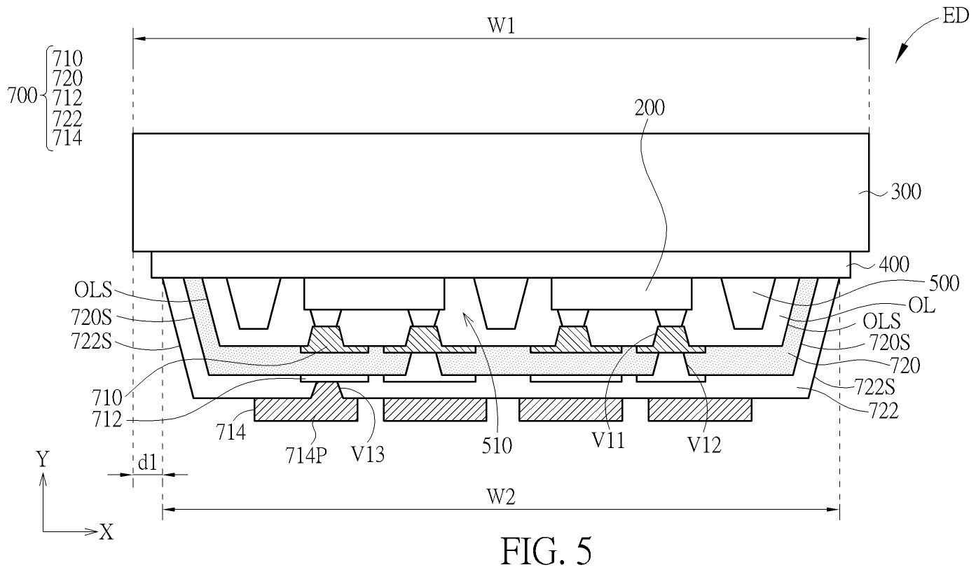

Please refer to FIG. 5, which is a cross-sectional schematic diagram of an electronic device according to a third embodiment of the present disclosure, wherein the electronic device ED shown in FIG. 5 may be manufactured by a chip-first process. According to the embodiment shown in FIG. 5, an electronic device ED may include a circuit layer 700, a plurality of semiconductor elements 200 and a covering layer 300. The plurality of semiconductor elements 200 may be electrically connected to the circuit layer 700 respectively, wherein the circuit layer 700 may include a conductive layer 710, an insulating layer 720, a conductive layer 712, an insulating layer 722 and a conductive layer 714 stacked in a direction opposite to the direction Y in sequence. In the cross-sectional view of the electronic device ED, the insulating layer 720 has two side-surfaces 720S which are opposite to each other, such as the surfaces at the left and right sides of the insulating layer 720 which are opposite to each other in the direction X in FIG. 5. The insulating layer 722 is in contact with the two side-surfaces 720S of the insulating layer 720, that is, the insulating layer 722 may contact and cover the two side-surfaces 720S of the insulating layer 720. The conductive layer 712 may be electrically connected to the conductive layer 710 through a connection hole V12 in the insulating layer 720, and the conductive layer 714 may be electrically connected to the conductive layer 712 through a connection hole V13 in the insulating layer 722, wherein the conductive layer 714 may include a plurality of conductive pads 714P. The plurality of semiconductor elements 200 are disposed on the conductive layer 710 and electrically connected to the conductive layer 710. The covering layer 300 is disposed on the plurality of semiconductor elements 200, wherein the covering layer 300 may be a substrate, for example. A width W1 of the covering layer 300 may be greater than a width W2 of the circuit layer 700, that is, a distance d1 may exist between an edge of the covering layer 300 and a corresponding adjacent edge of the circuit layer 700 (or the insulating layer 722) in the direction X.

According to the embodiment shown in FIG. 5, the electronic device ED may further include an encapsulation layer OL configured to encapsulate the plurality of semiconductor elements 200, and the conductive layer 710 may be electrically connected to the semiconductor elements 200 through a connection hole V11 in the encapsulation layer OL. In the cross-sectional view of the electronic device ED, the encapsulation layer OL has two side-surfaces OLS which are opposite to each other, such as the surfaces at the left and right sides of the encapsulation layer OL which are opposite to each other in the direction X in FIG. 5. The insulating layer 720 may be in contact with the two side-surfaces OLS of the encapsulation layer OL, that is, the insulating layer 720 may contact and cover the two side-surfaces OLS of the encapsulation layer OL. In some embodiments, as shown in FIG. 5, the electronic device ED may further include an adhesive layer 400 disposed between the covering layer 300 and the plurality of semiconductor elements 200. In addition, the electronic device ED may further include a shielding layer 500 disposed between the adhesive layer 400 and the encapsulation layer OL. The shielding layer 500 may have a plurality of through-holes 510, and at least one of the plurality of semiconductor elements 200 is disposed in one of the plurality of through-holes 510.

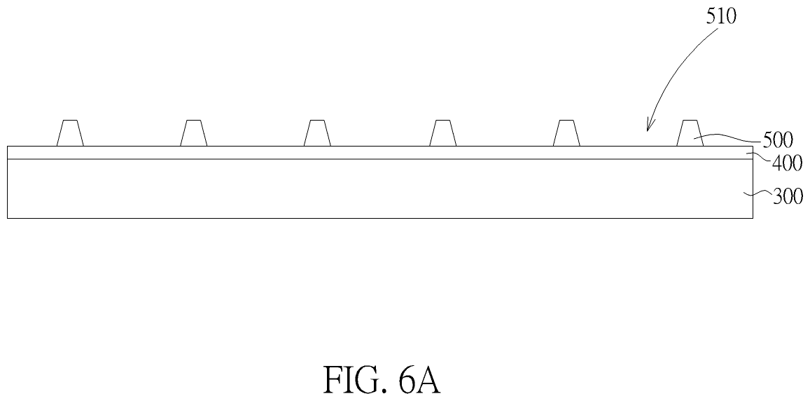

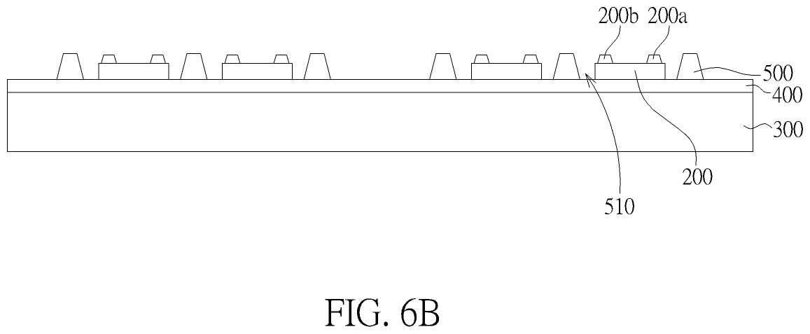

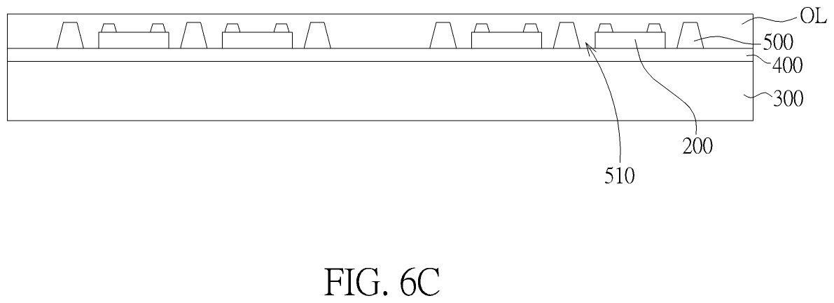

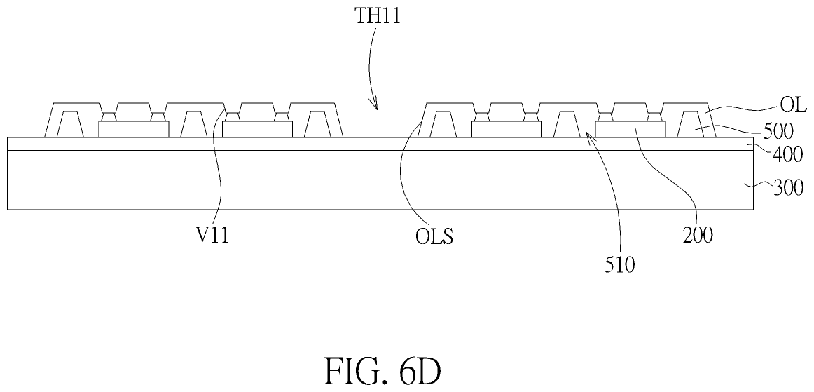

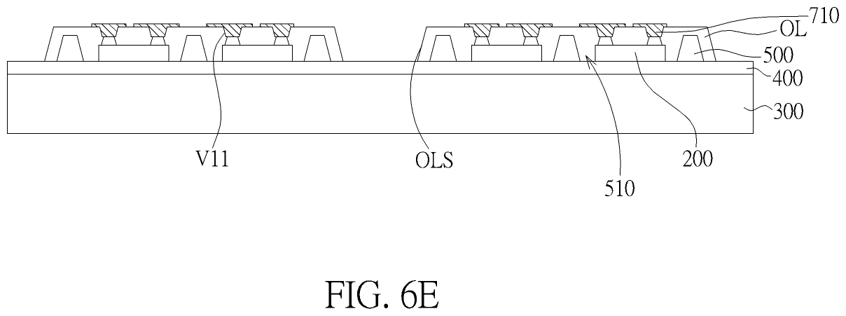

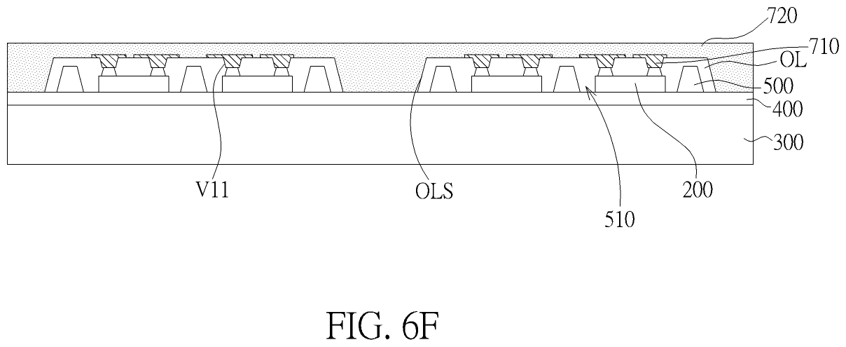

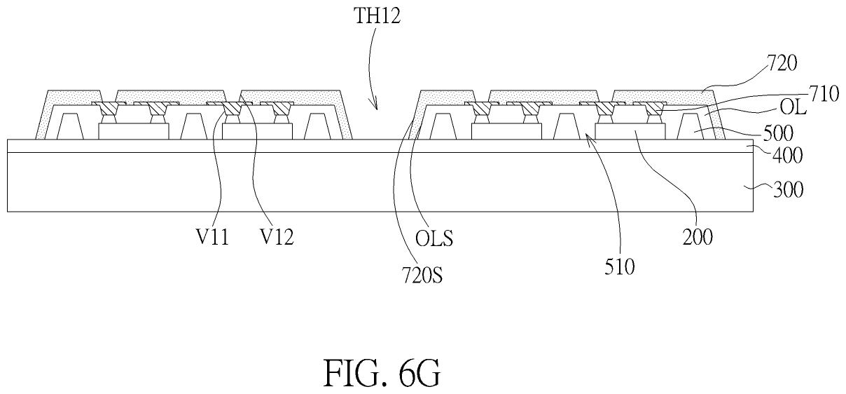

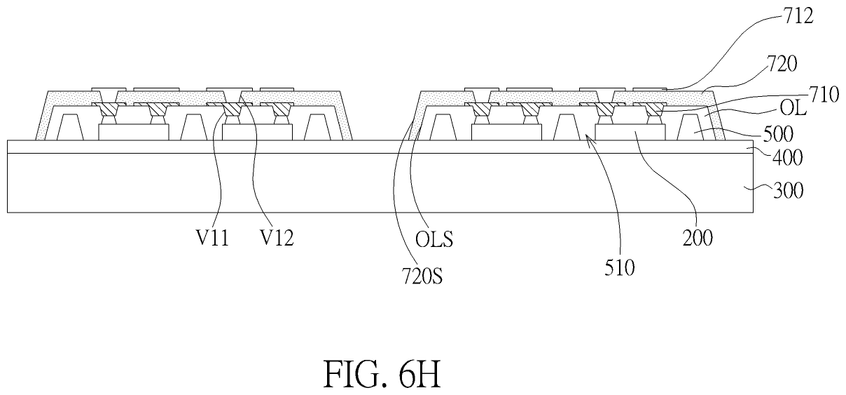

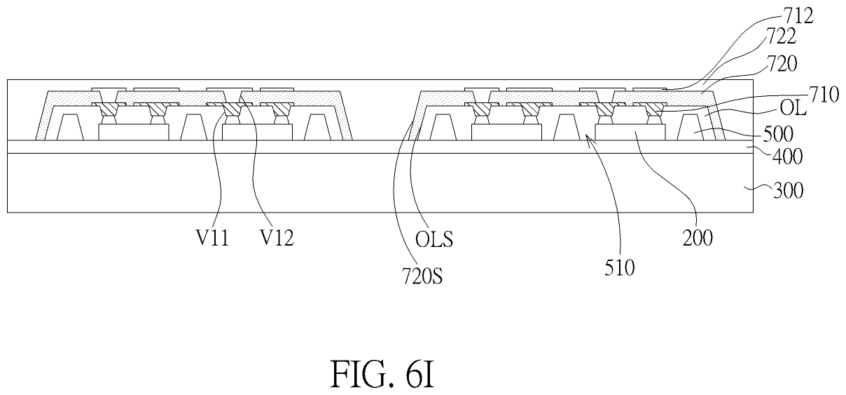

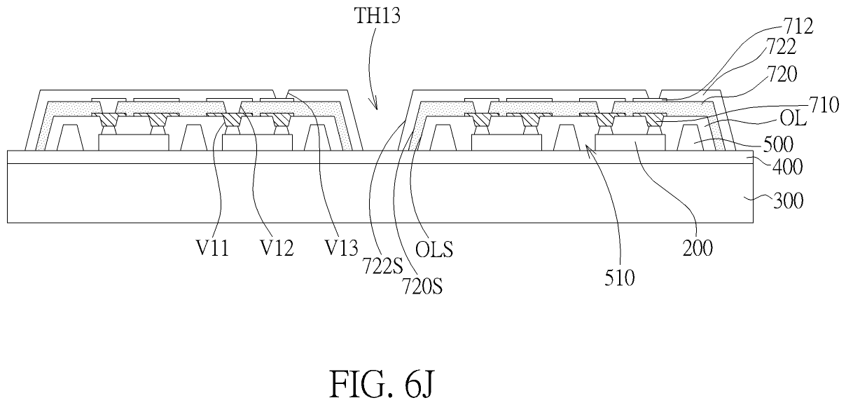

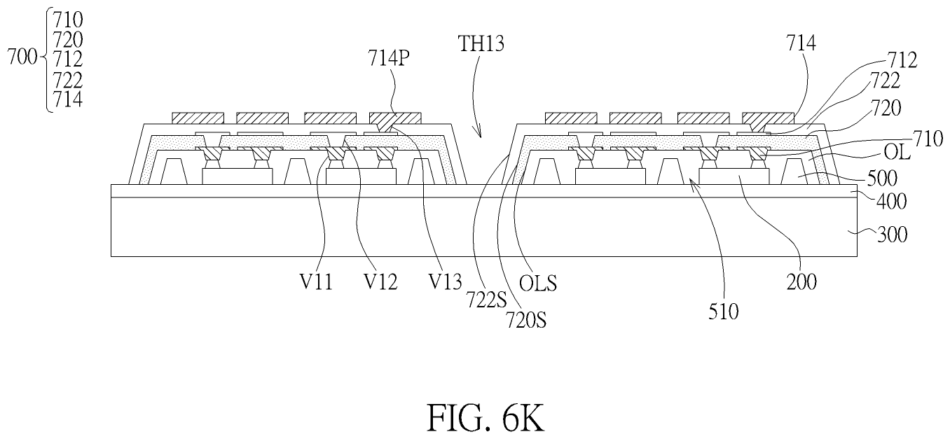

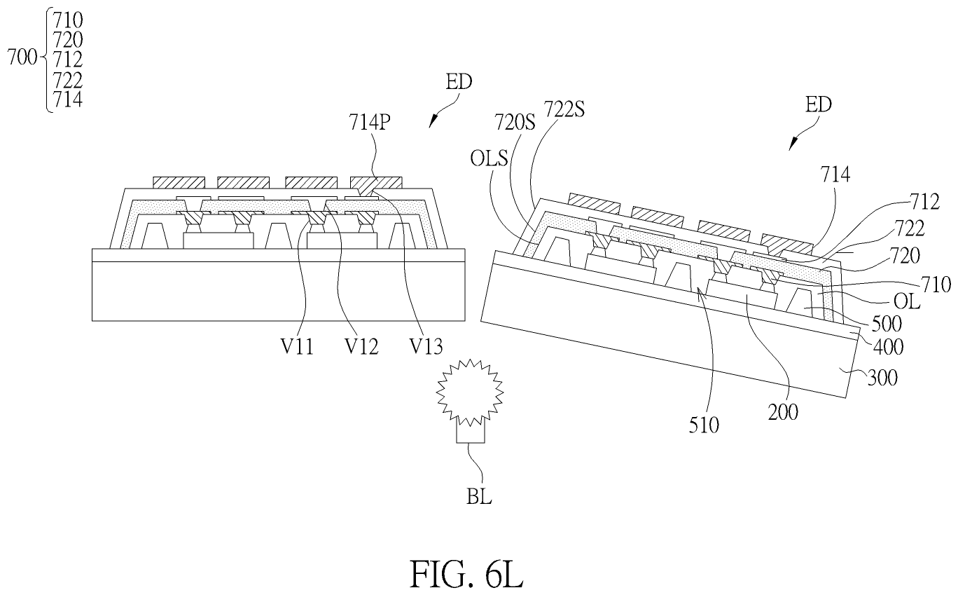

Please refer to FIG. 6A to FIG. 6L. FIG. 6A to FIG. 6L are schematic diagrams illustrating the process of a method for manufacturing an electronic device according to a third embodiment of the present disclosure. Specifically, as shown in FIG. 6A, first, the covering layer 300 may be provided, wherein the covering layer 300 may be a substrate, for example. Then, the adhesive layer 400 may be formed on the covering layer 300, and then the shielding layer 500 may be formed on the adhesive layer 400, wherein the shielding layer 500 may have a plurality of through-holes 510. As shown in FIG. 6B, then, a plurality of semiconductor elements 200 may be disposed on the covering layer 300. For example, each semiconductor element 200 may be disposed in one of the through-holes 510 with the way that the surface of the semiconductor element 200 which the first electrode 200a and the second electrode 200b arranged on being face-up, and the plurality of semiconductor elements 200 may be attached to the covering layer 300 through the adhesive layer 400. As shown in FIG. 6C, then, the encapsulation layer OL may be disposed on the semiconductor elements 200, so that the encapsulation layer OL surrounds and encapsulates the semiconductor elements 200.

As shown in FIG. 6D, then, the encapsulation layer OL may be patterned to form a through-hole TH11 and a plurality of connection holes V11, wherein in the cross-sectional view, the encapsulation layer OL has a side-surface OLS corresponding to the through-hole TH11. The side-surface OLS of the encapsulation layer OL may be adjacent to the through-hole TH11 or define the through-hole TH11, that is, a side wall of the through-hole TH11 may be regarded as the side-surface OLS of the encapsulation layer OL. Then, as shown in FIG. 6E, the patterned conductive layer 710 may be formed on the encapsulation layer OL, and the conductive layer 710 is electrically connected to the semiconductor elements 200 through the connection holes V11. Through a photolithography process, the connection holes V11 and the through-hole TH11 may be formed in the encapsulation layer OL at the same time, wherein forming the through-hole TH11 earlier in this step may effectively reduce the complexity of the structure within the through-hole TH11. In some embodiments, a portion of the adhesive layer 400 may be removed (not shown) when forming the connection holes V11 and the through-hole TH11, so that a distance exists between an edge of the covering layer 300 and a corresponding adjacent edge of the adhesive layer 400, similar to the structure of the electronic device ED shown in FIG. 5, but not limited herein.

Then, as shown in FIG. 6F, the insulating layer 720 may be formed on the encapsulation layer OL and the conductive layer 710. Then, as shown in FIG. 6G, the insulating layer 720 may be patterned to form a through-hole TH12 and a plurality of connection holes V12, wherein a size of the formed through-hole TH12 may be less than a size of the through-hole TH11 (that is, the minimum width of the through-hole TH12 is less than the minimum width of the through-hole TH11), so that the insulating layer 720 may contact the side-surface OLS of the encapsulation layer OL after patterning the insulating layer 720. In the cross-sectional view, the insulating layer 720 has a side-surface 720S corresponding to the through-hole TH12. The side-surface 720S of the insulating layer 720 may be adjacent to the through hole TH12 or define the through hole TH12, that is, a side wall of the through-hole TH12 may be regarded as the side-surface 720S of the insulating layer 720. Then, as shown in FIG. 6H, the patterned conductive layer 712 may be formed on the insulating layer 720, and the conductive layer 712 is electrically connected to the conductive layer 710 through the connection holes V12.

Then, as shown in FIG. 6I, the insulating layer 722 may be formed on the insulating layer 720 and the conductive layer 712. Then, as shown in FIG. 6J, the insulating layer 722 is patterned to form a through-hole TH13 and a plurality of connection holes V13, wherein a size of the formed through-hole TH13 may be less than the size of the through-hole TH12 (that is, the minimum width of the through-hole TH13 is less than the minimum width of the through-hole TH12), so that the insulating layer 722 may contact the side-surface 720S of the insulating layer 720 after patterning the insulating layer 722. In the cross-sectional view, the insulating layer 722 has a side-surface 722S corresponding to the through-hole TH13. The side-surface 722S of the insulating layer 722 may be adjacent to the through-hole TH13 or define the through hole TH13, that is, a side wall of the through-hole TH13 may be regarded as the side-surface 722S of the insulating layer 722.

Then, as shown in FIG. 6K, the patterned conductive layer 714 may be formed on the insulating layer 722, and the conductive layer 714 may be electrically connected to the conductive layer 712 through the connection holes V13, wherein the conductive layer 714 may include a plurality of conductive pads 714P, such that the manufacturing of the circuit layer 700 may be completed. Then, as shown in FIG. 6L, the covering layer 300 and the adhesive layer 400 may be cut, which may be achieved by a laser cutting process or a cutting-wheel cutting process performed through a cutting-wheel BL as shown in FIG. 6L, for example. The position of the above through-hole TH13 (i.e., the corresponding positions of the through-hole TH11 and the through-hole TH12) may be regarded as the position of the cutting path. Then, a plurality of electronic devices ED may be obtained by flipping the whole structure upside down. In some embodiments, a portion of the adhesive layer 400 is removed at the same time when the connection holes V11 and the through-hole TH11 are formed, so that a distance exists between the edge of the covering layer 300 and the corresponding adjacent edge of the adhesive layer 400, then a plurality of structures of electronic devices ED as shown in FIG. 5 may be obtained after cutting, but not limited herein.

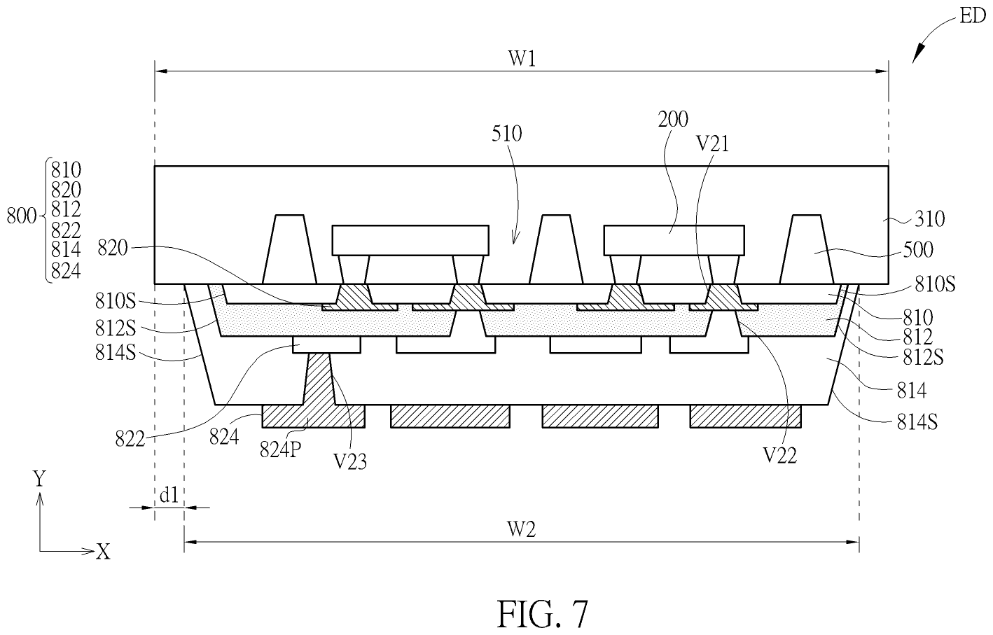

Please refer to FIG. 7, which is a cross-sectional schematic diagram of an electronic device according to a fourth embodiment of the present disclosure, wherein the electronic device ED shown in FIG. 7 may be manufactured by a chip-first process. According to the embodiment shown in FIG. 7, an electronic device ED may include a circuit layer 800, a plurality of semiconductor elements 200 and a covering layer 310. The plurality of semiconductor elements 200 may be electrically connected to the circuit layer 800 respectively, wherein the circuit layer 800 may include an insulating layer 810, a conductive layer 820, an insulating layer 812, a conductive layer 822, an insulating layer 814 and a conductive layer 824 stacked in a direction opposite to the direction Y in sequence. In the cross-sectional view of the electronic device ED, the insulating layer 810 has two side-surfaces 810S which are opposite to each other, such as the surfaces at the left and right sides of the insulating layer 810 which are opposite to each other in the direction X in FIG. 7, and the insulating layer 812 has two side-surfaces 812S which are opposite to each other, such as the surfaces at the left and right sides of the insulating layer 812 which are opposite to each other in the direction X in FIG. 7. The insulating layer 812 may contact and cover the two side-surfaces 810S of the insulating layer 810, and the insulating layer 814 may contact and cover the two side-surfaces 812S of the insulating layer 812. The conductive layer 822 may be electrically connected to the conductive layer 820 through a connection hole V22 in the insulating layer 812, and the conductive layer 824 may be electrically connected to the conductive layer 822 through a connection hole V23 in the insulating layer 814, wherein the conductive layer 824 may include a plurality of conductive pads 824P.

The plurality of semiconductor elements 200 are disposed on the conductive layer 820 and electrically connected to the conductive layer 820, that is, the conductive layer 820 may be electrically connected to the semiconductor elements 200 through connection holes V21 in the insulating layer 810. The covering layer 310 is disposed on the plurality of semiconductor elements 200, wherein the covering layer 310 may be configured to encapsulate the semiconductor elements 200, that is, the covering layer 310 may be an encapsulation layer, for example. A width W1 of the covering layer 310 may be greater than a width W2 of the circuit layer 800, that is, a distance d1 may exist between an edge of the covering layer 310 and a corresponding adjacent edge of the circuit layer 800 (or the insulating layer 814) in the direction X.

In some embodiments, as shown in FIG. 7, the electronic device ED may further include a shielding layer 500 disposed on the circuit layer 800, such as disposed on the insulating layer 810. The shielding layer 500 may have a plurality of through-holes 510, at least one of the semiconductor elements 200 is disposed in one of the through-holes 510, and the covering layer 310 surrounds the semiconductor elements 200 and the shielding layer 500. In an embodiment, the shielding layer 500 may enable the corresponding semiconductor element 200 to diffuse light when the semiconductor element 200 is a light emitting element. In contrast, in the embodiment shown in FIG. 5, the shielding layer 500 may limit the signal emitted by the corresponding semiconductor element 200 when the semiconductor element 200 is a light emitting element, such as achieving the effect of limiting the emitting-angle of the signal thereof to the right above.

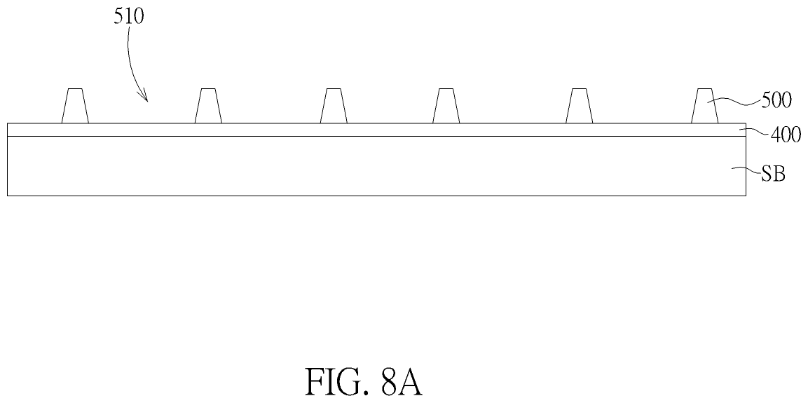

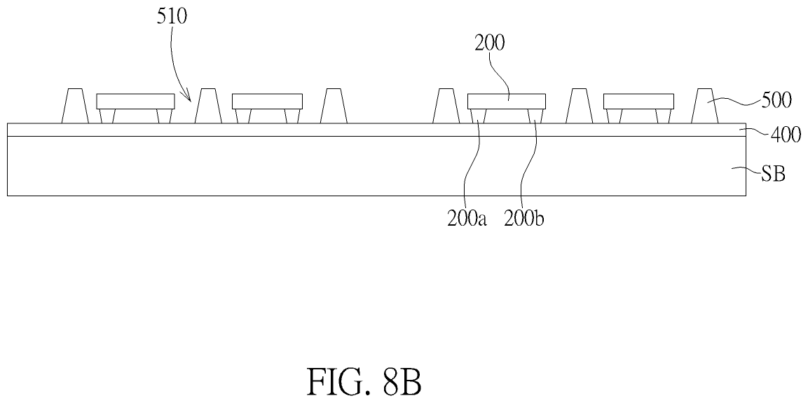

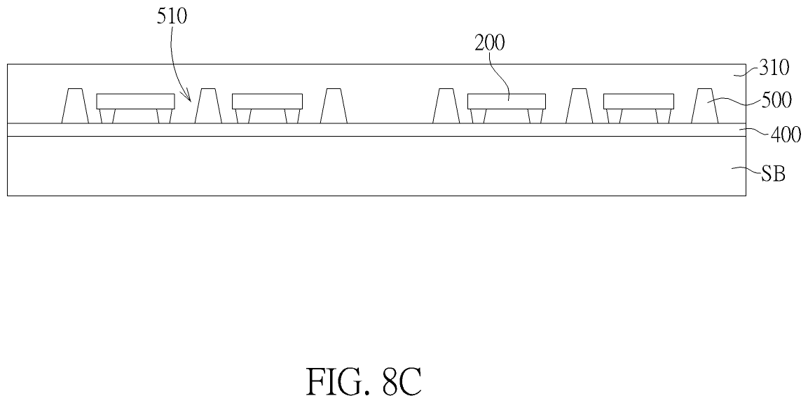

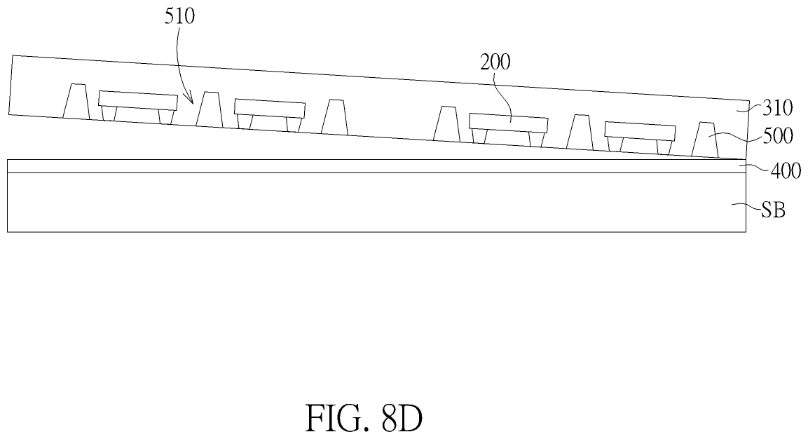

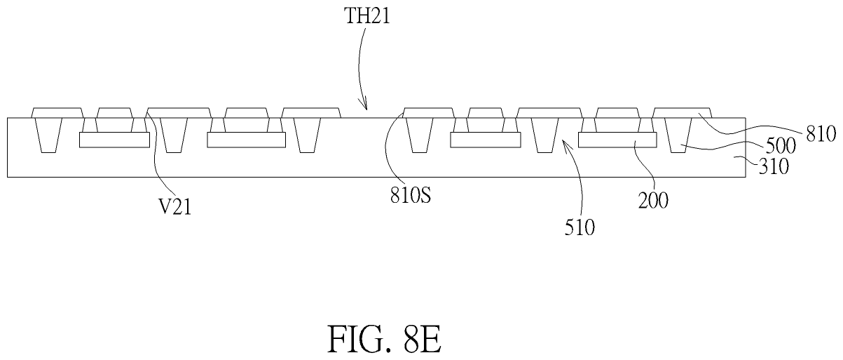

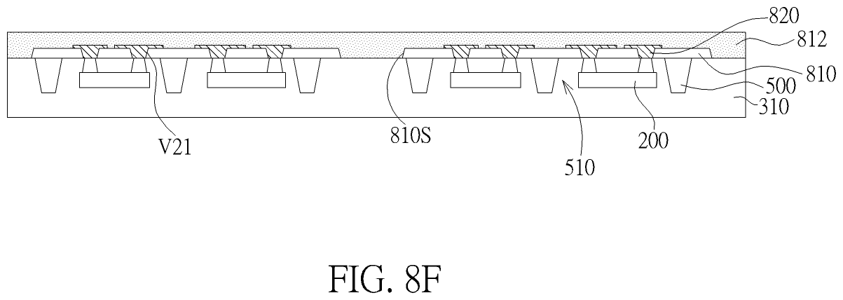

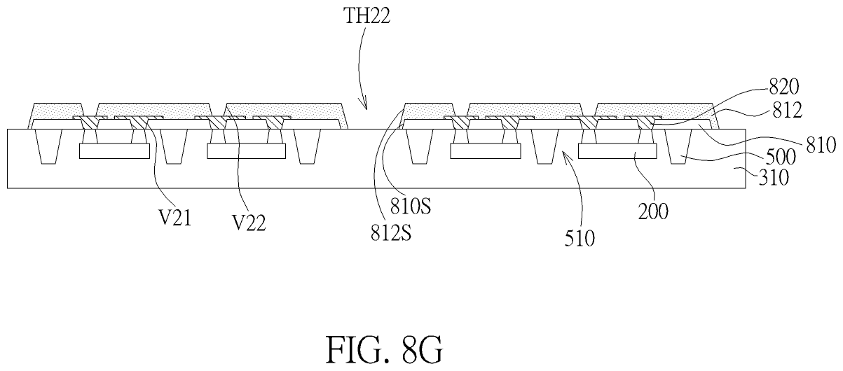

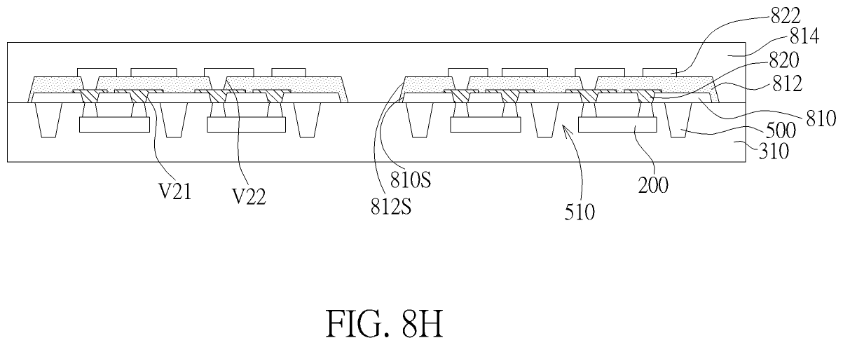

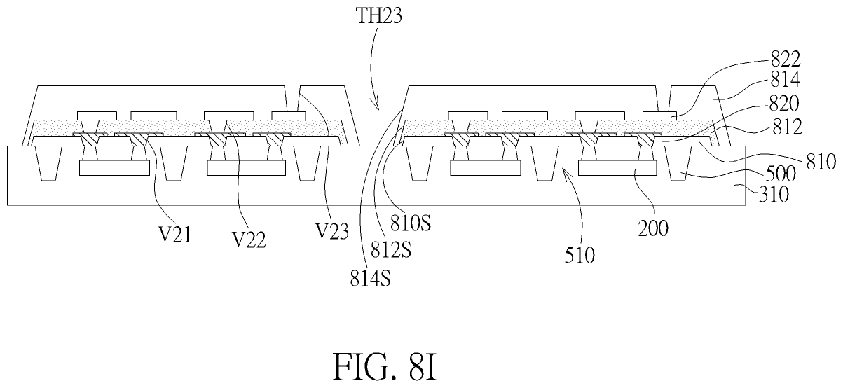

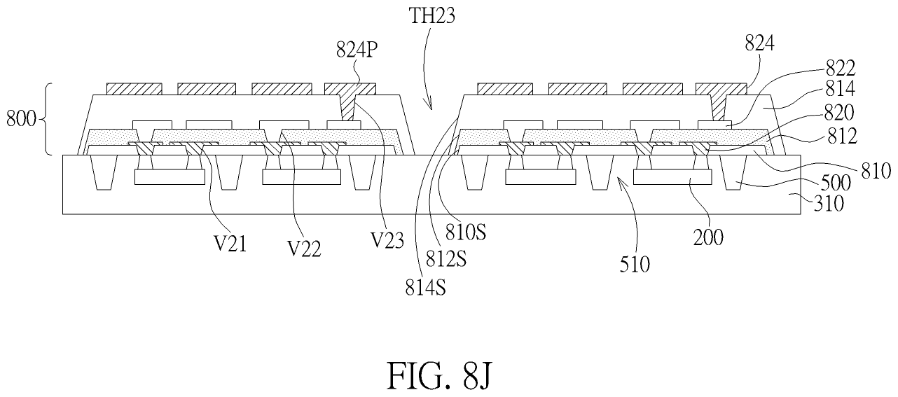

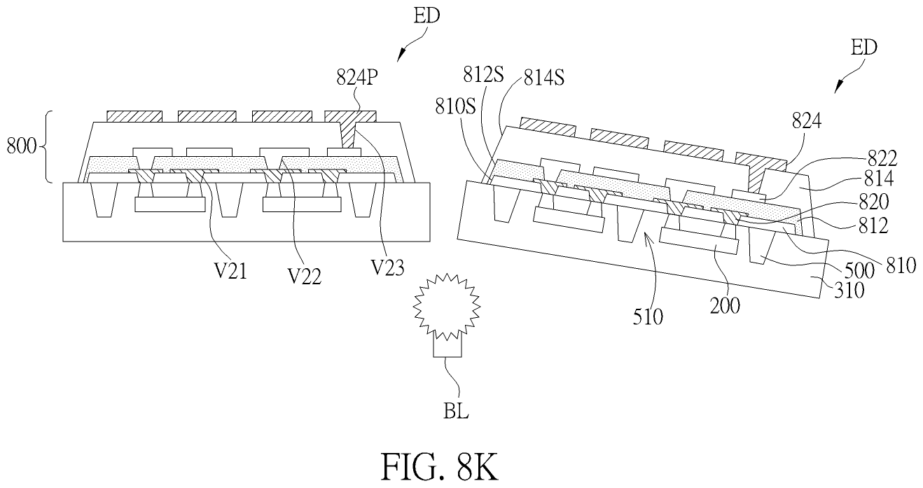

Please refer to FIG. 8A to FIG. 8K. FIG. 8A to FIG. 8K are schematic diagrams illustrating the process of a method for manufacturing an electronic device according to a fourth embodiment of the present disclosure. Specifically, as shown in FIG. 8A, first, a substrate SB may be provided. Then, an adhesive layer 400 may be formed on the substrate SB, and then the shielding layer 500 may be formed on the adhesive layer 400, wherein the shielding layer 500 may have a plurality of through-holes 510. As shown in FIG. 8B, then, a plurality of semiconductor elements 200 may be disposed on the substrate SB. For example, each semiconductor element 200 may be disposed in one of the through-holes 510 with the way that the surface of the semiconductor element 200 which the first electrode 200a and the second electrode 200b arranged on being face-down, and the plurality of semiconductor elements 200 may be attached to the substrate SB through the adhesive layer 400. As shown in FIG. 8C, then, the covering layer 310 may be disposed on the semiconductor elements 200, so that the covering layer 310 surrounds and encapsulates the semiconductor elements 200. Then, as shown in FIG. 8D, the adhesive layer 400 and the substrate SB may be removed.

Then as shown in FIG. 8E, the whole structure may be flipped upside down, and the patterned insulating layer 810 may be formed on the covering layer 310. The patterned insulating layer 810 has a through-hole TH21 and a plurality of connection holes V21, wherein in the cross-sectional view, the insulating layer 810 has a side-surface 810S corresponding to the through-hole TH21. The side-surface 810S of the insulating layer 810 may be adjacent to the through-hole TH21 or define the through-hole TH21, that is, a side wall of the through-hole TH21 may be regarded as the side-surface 810S of the insulating layer 810. Through a photolithography process, the connection holes V21 and the through-hole TH21 may be formed in the insulating layer 810 at the same time, wherein forming the through-hole TH21 earlier in this step may effectively reduce the complexity of the structure within the through-hole TH21.

Then as shown in FIG. 8F, the conductive layer 820 may be formed on the insulating layer 810, and the conductive layer 820 is electrically connected to the semiconductor elements 200 through the connection holes V21. Then, the insulating layer 812 may be formed on the insulating layer 810 and the conductive layer 820. Then as shown in FIG. 8G, the insulating layer 812 may be patterned to form a through-hole TH22 and a plurality of connection holes V22, wherein a size of the formed through-hole TH22 may be less than a size of the through-hole TH21 (that is, the minimum width of the through-hole TH22 is less than the minimum width of the through-hole TH21), so that the insulating layer 812 may contact the side-surface 810S of the insulating layer 810 after patterning the insulating layer 812. In the cross-sectional view, the insulating layer 812 has a side-surface 812S corresponding to the through-hole TH22. The side-surface 812S of the insulating layer 812 may be adjacent to the through hole TH22 or define the through hole TH22, that is, a side wall of the through-hole TH22 may be regarded as the side-surface 812S of the insulating layer 812.

Then, as shown in FIG. 8H, the conductive layer 822 may be formed on the insulating layer 812, and the conductive layer 822 may be electrically connected to the conductive layer 820 through the connection holes V22. Then, the insulating layer 814 may be formed on the insulating layer 812 and the conductive layer 822. Then, as shown in FIG. 81, the insulating layer 814 is patterned to form a through-hole TH23 and a plurality of connection holes V23, wherein a size of the formed through-hole TH23 may be less than the size of the through-hole TH22 (that is, the minimum width of the through-hole TH23 is less than the minimum width of the through-hole TH22), so that the insulating layer 814 may contact the side-surface 812S of the insulating layer 812 after patterning the insulating layer 814. In the cross-sectional view, the insulating layer 814 has a side-surface 814S corresponding to the through-hole TH23. The side-surface 814S of the insulating layer 814 may be adjacent to the through-hole TH23 or define the through hole TH23, that is, a side wall of the through-hole TH23 may be regarded as the side-surface 814S of the insulating layer 814.

Then, as shown in FIG. 8J, the conductive layer 824 may be formed on the insulating layer 814, and the conductive layer 824 may be electrically connected to the conductive layer 822 through the connection holes V23, wherein the conductive layer 824 may include a plurality of conductive pads 824P, such that the manufacturing of the circuit layer 800 may be completed. Then, as shown in FIG. 8K, the covering layer 310 may be cut, which may be achieved by a laser cutting process or a cutting process performed through a cutting-wheel BL as shown in FIG. 8K, for example. The position of the above through-hole TH23 (i.e., the corresponding positions of the through-hole TH21 and the through-hole TH22) may be regarded as the position of the cutting path. Then, a plurality of electronic devices ED as shown in FIG. 7 may be obtained by flipping the whole structure upside down.

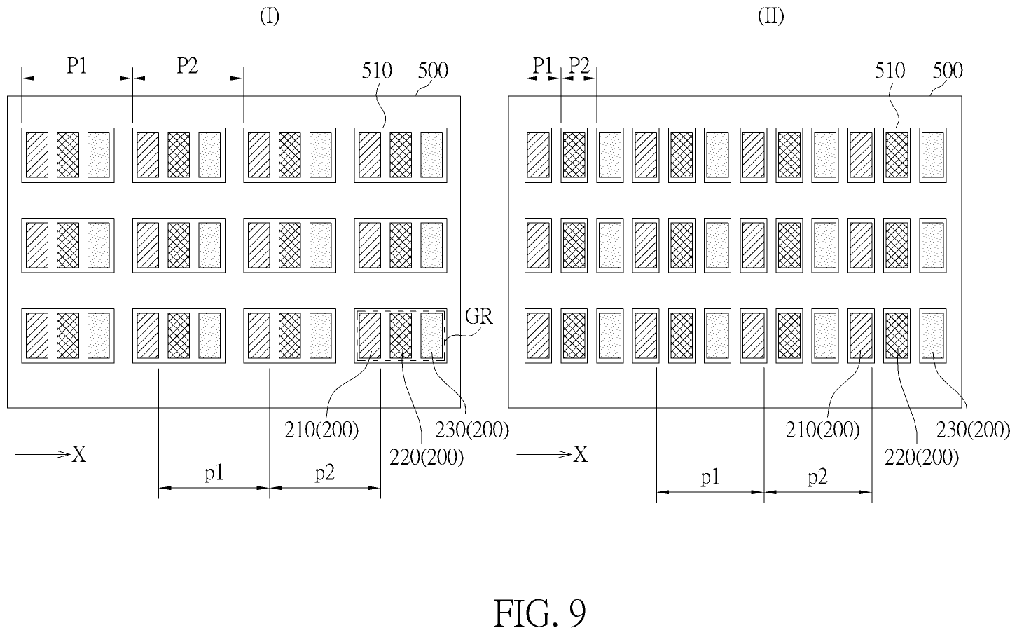

Please refer to FIG. 9, which is a top-view schematic diagram of embodiments of semiconductor elements and a shielding layer according to an electronic device of the present disclosure. As shown in an example (I) and an example (II) of FIG. 9, the plurality of semiconductor elements 200 may be arranged in an array and surrounded by the shielding layer 500, and the plurality of semiconductor elements 200 may include a semiconductor element 210, a semiconductor element 220 and a semiconductor element 230 with the same function or property, or at least one of the semiconductor elements has a different function or property from other semiconductor elements. In an embodiment, for example, when the electronic device ED is a display device, the semiconductor element 210, the semiconductor element 220 and the semiconductor element 230 may be light emitting elements, such as representing light emitting elements that can emit red light, green light and blue light respectively, but not limited herein. In the example (I) of FIG. 9, the semiconductor element 210, the semiconductor element 220 and the semiconductor element 230 may form a semiconductor unit GR as a whole and are disposed in one of the plurality of through-holes 510 of the shielding layer 500 at the same time, wherein the semiconductor element 210, the semiconductor element 220 and the semiconductor element 230 serving as one group of semiconductor unit GR may be regarded as a pixel, but not limited herein. In the example (II) of FIG. 9, the semiconductor element 210, the semiconductor element 220 and the semiconductor element 230 may be respectively disposed in different through-holes 510 of the shielding layer 500. According to the example (I) and example (II) of FIG. 9, when placing the semiconductor elements 200, different semiconductor elements 200 may have different pitches. Therefore, two adjacent semiconductor elements 200 emitting the same color light (i.e., two adjacent semiconductor elements 210, two adjacent semiconductor elements 220 or two adjacent semiconductor elements 230) may have the same or different pitches in the direction X. For example, a ratio of a pitch p1 to a pitch p2 may range from 0.8 to 1.2, or the pitch p1 is different from the pitch p2, wherein the pitch p1 or the pitch p2 may be measured from a side of one semiconductor element 210 to the corresponding same side of the adjacent another one semiconductor element 210 along the direction X, for example. Furthermore, two adjacent through-holes 510 of the shielding layer 500 may have the same pitch in the direction X to improve the visual effect. For example, a pitch P1 is equal to a pitch P2, wherein the pitch P1 or the pitch P2 can be measured from a side of one through-hole 510 to the corresponding same side of the another one through-hole 510 along the direction X.

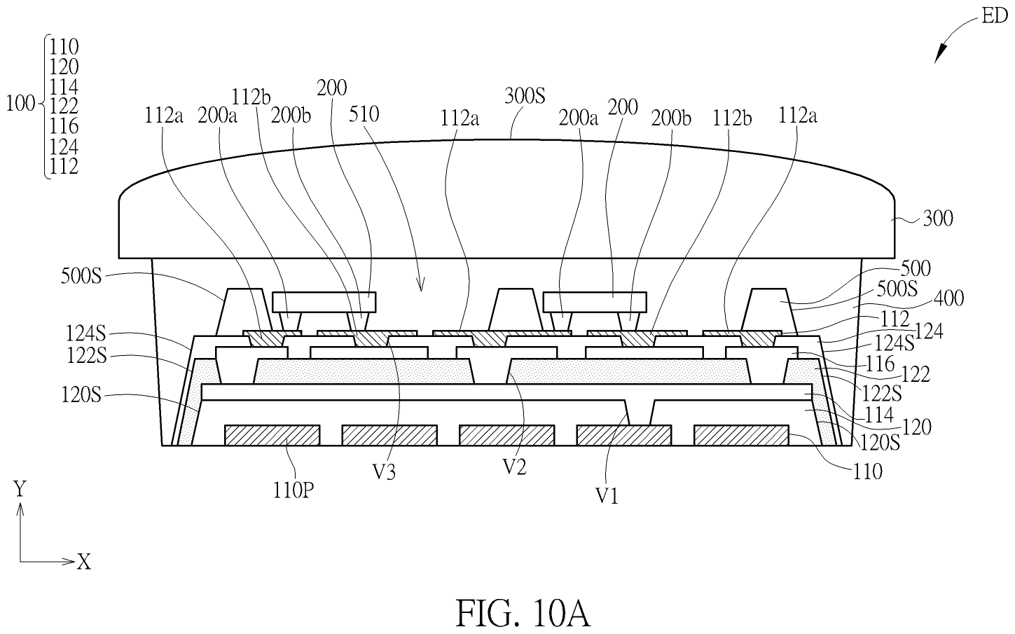

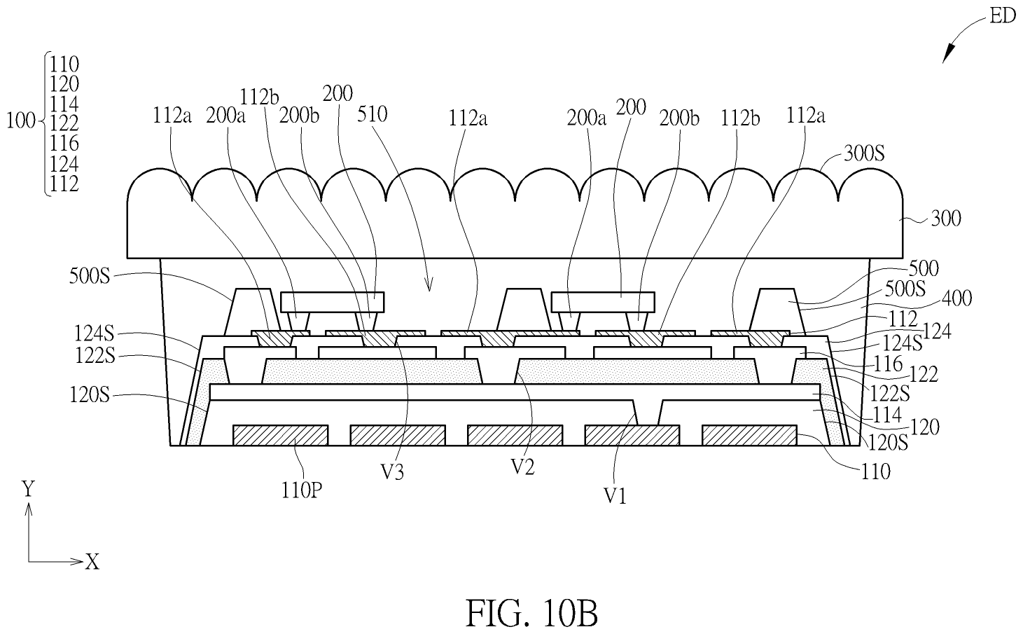

Please refer to FIG. 10A and 10B. FIG. 10A and FIG. 10B are cross-sectional schematic diagrams of various embodiments of an electronic device of the present disclosure. As shown in FIG. 10A and FIG. 10B, a surface 300S of the covering layer 300 may be treated to form a lens structure or a rough structure, so as to improve the light exiting efficiency. The above structures may be formed by a physical grinding process or a chemical etching process, for example, wherein the surface 300S may be located at a side opposite to the semiconductor elements 200. In some embodiments, the lens structure or the rough structure may be formed on the upper surface of the covering layer 300 shown in FIG. 1 or FIG. 5 or the upper surface of the covering layer 310 shown in FIG. 2 or FIG. 7.

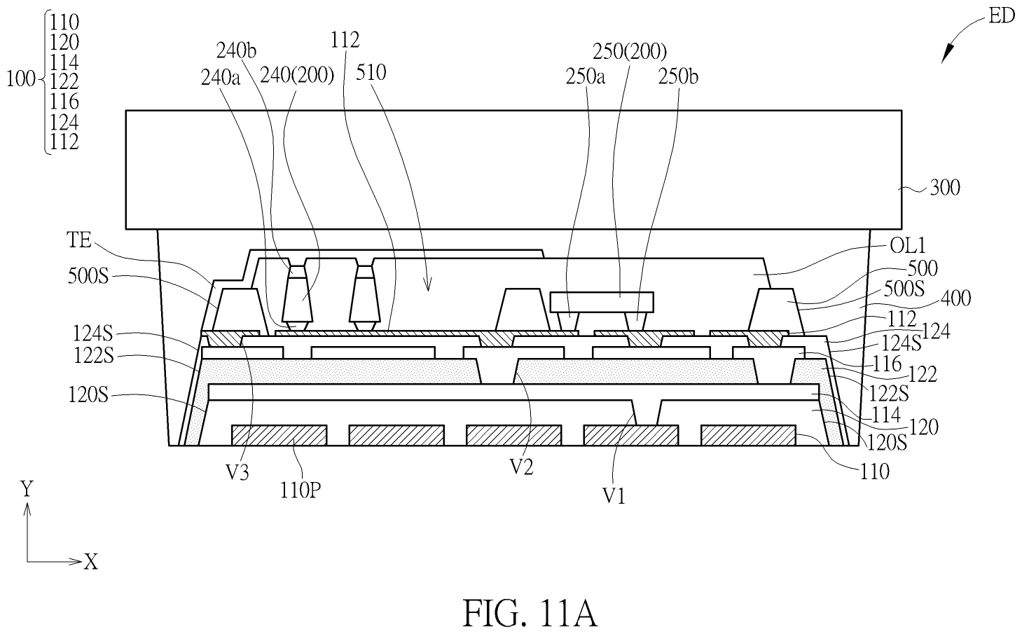

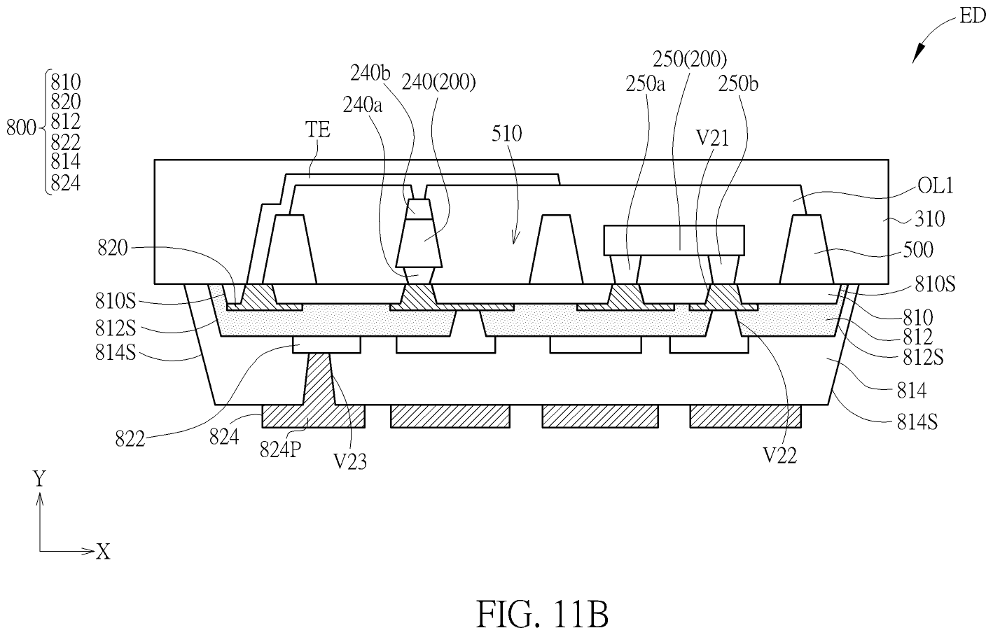

Please refer to FIG. 11A and FIG. 11B. FIG. 11A and FIG. 11B are cross-sectional schematic diagrams of further embodiments of an electronic device of the present disclosure. As shown in FIG. 11A and FIG. 11B, the plurality of semiconductor elements 200 may include a semiconductor element 240 and a semiconductor element 250, and the semiconductor element 240 and the semiconductor element 250 may be surrounded and encapsulated by an encapsulation layer OL1. The semiconductor element 240 may include a first electrode 240a and a second electrode 240b opposite to each other in the direction Y, and the semiconductor element 250 may include a first electrode 250a and a second electrode 250b adjacent to each other in the direction X. In an embodiment, when the electronic device ED is a display device, the semiconductor element 240 and the semiconductor element 250 may be light emitting elements. The semiconductor element 240 may be a vertical-type light emitting element and may emit red light, for example, so that the light emitting efficiency thereof may be improved or the connection area of the electrodes may be increased, wherein a thickness of the semiconductor element 240 in the direction Y may be, for example, 4 micrometers to 8 micrometers, so as to improve the stability of structure. The semiconductor element 250 may be a planar-type light emitting element or a flip-chip light emitting element and may emit blue light or green light, for example, wherein a thickness of the semiconductor element 250 in the direction Y may be, for example, 2 micrometers to 4 micrometers. That is to say, the thickness of the semiconductor element 250 may be thinner than the thickness of the semiconductor element 240, so as to make the elements thinner.

According to the electronic device ED shown in FIG. 11A, the first electrode 240a of the semiconductor element 240 may be disposed on the conductive layer 112 and electrically connected to the conductive layer 110 through the patterned conductive layer 112, conductive layer 116 and conductive layer 114, and the second electrode 240b of the semiconductor element 240 may be electrically connected to the patterned conductive layer 112 and conductive layer 116 through a conductive layer TE disposed on the surface of the encapsulation layer OL1 and extending to the outer-surface 500S of the shielding layer 500. The conductive layer TE is a transparent conductive layer, including indium tin oxide (ITO) or indium zinc oxide (IZO), for example, but not limited herein. The first electrode 250a and the second electrode 250b of the semiconductor element 250 may be disposed on the conductive layer 112. The first electrode 250a is electrically connected to the conductive layer 110 through the patterned conductive layer 112, conductive layer 116 and conductive layer 114, and the second electrode 250b is electrically connected to the patterned conductive layer 112 and conductive layer 116.

According to the electronic device ED shown in FIG. 11B, the first electrode 240a of the semiconductor element 240 may be disposed on the conductive layer 820 and electrically connected to the conductive layer 824 through the patterned conductive layer 820 and conductive layer 822, and the second electrode 240b of the semiconductor element 240 may be electrically connected to the patterned conductive layer 820 through a conductive layer TE disposed on the surface of the encapsulation layer OL1 and extending to the outer-surface 500S of the shielding layer 500. The first electrode 250a and the second electrode 250b of the semiconductor element 250 may be disposed on the conductive layer 820 and electrically connected to the conductive layer 820.

Please refer to FIG. 12, which is a cross-sectional schematic diagram of an embodiment that an electronic device of the present disclosure is bonded to another device. As shown in FIG. 12, the electronic device ED may be bonded to a device DD correspondingly, wherein the electronic device ED may be any one of the electronic devices ED manufactured by an RDL-first process or a chip-first process in the previous embodiments. In FIG. 12, the electronic device ED shown in FIG. 11B is used as an example, but not limited herein. The device DD may include a circuit layer 900 and a control element 1000, and the control element 1000 may be electrically connected to the circuit layer 800 of the electronic device ED through the circuit layer 900, wherein the control element 1000 may be, for example (but not limited to), a driving element, an integrated circuit chip or a microcircuit chip (Micro IC). In some embodiments, the device DD may further include an encapsulation layer OL2, an adhesive layer 410 and a substrate SB1. The control element 1000 may be surrounded by the encapsulation layer OL2 and attached to the substrate SB1 through the adhesive layer 410, and the circuit layer 900 may be disposed on the control element 1000.

According to the device DD shown in FIG. 12, the circuit layer 900 may include a conductive layer 910, an insulating layer 920, a conductive layer 912, an insulating layer 922, and a conductive layer 914 stacked in the direction Y in sequence, so as to redistribute the circuit. For example, through the wiring process, the contact positions of the wirings may be changed and/or the fan-out area of the wiring may be increased, Specifically, in the cross-sectional view, the insulating layer 920 may contact and cover two opposite side-surfaces of the encapsulation layer OL2, and the insulating layer 922 may contact and cover two opposite side-surfaces of the insulating layer 920. The control element 1000 may include a plurality of conductive pads 1000P. The patterned conductive layer 910 may be electrically connected to the conductive pads 1000P of the control element 1000 through connection holes in the encapsulation layer OL2, the patterned conductive layer 912 may be electrically connected to the conductive layer 910 through connection holes in the insulating layer 920, and the patterned conductive layer 914 may be electrically connected to the conductive layer 912 through connection holes in the insulating layer 922, wherein the conductive layer 914 may include a plurality of conductive pads 914P.

One of the plurality of conductive pads 824P of the electronic device ED may be connected to one of the plurality of conductive pads 914P of the device DD respectively. For example, the conductive pads 824P may be electrically connected to the conductive pads 914P through connection elements (not shown) such as solder balls, but not limited herein. That is to say, a number of the conductive pads 824P may correspond to or be the same as a number of the conductive pads 914P, and the arranging positions of the conductive pads 824P and the conductive pads 914P may correspond to each other. Therefore, in the electronic device ED, the wirings of the circuit layer 800 may be integrated and merged to reduce the number of the conductive pads. For example, the number of the conductive pads in the conductive layer 820 electrically connected to the electrodes of the semiconductor elements 200 may be reduced and integrated as the plurality of conductive pads 824P. Furthermore, in the device DD, the circuit layer 900 may change the contact positions of the wirings and increase the fan-out area of the wiring. For example, the conductive pads 1000P of the control element 1000 may be redistributed as the conductive pads 914P by fanned-out method. According to the above structural design, the conductive pads 824P of the electronic device ED and the conductive pads 914P of the device DD may be bonded more easily and effectively, thereby improving the connection effect between the electronic device ED and the device DD.

From the above description, according to the electronic devices and related manufacturing methods of the embodiments of the present disclosure, through the upper insulating layer contacting the side-surface of the lower insulating layer, a better protection effect may be provided, thereby improving the reliability of the electronic device. Furthermore, through the method of forming the connection holes and the through-holes step by step and layer by layer, the depths of the through-holes may be effectively reduced, and the subsequent cutting process may be completed more easily.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a first conductive layer;
a first insulating layer disposed on the first conductive layer, wherein in a cross-sectional view of the electronic device, the first insulating layer has two side-surfaces which are opposite to each other;
a second insulating layer disposed on the first insulating layer and in contact with the two side-surfaces of the first insulating layer;
a second conductive layer disposed on the second insulating layer and electrically connected to the first conductive layer;
a plurality of semiconductor elements disposed on and electrically connected to the second conductive layer; and
a covering layer disposed on the plurality of semiconductor elements.

2. The electronic device as claimed in claim 1, further comprising an adhesive layer disposed between the covering layer and the plurality of semiconductor elements.

3. The electronic device as claimed in claim 2, wherein, in the cross-sectional view of the electronic device, the second insulating layer has two side-surfaces which are opposite to each other, and the adhesive layer contacts the two side-surfaces of the second insulating layer.

4. The electronic device as claimed in claim 1, wherein the covering layer is configured to encapsulate the plurality of semiconductor elements.

5. The electronic device as claimed in claim 4, wherein, in the cross-sectional view of the electronic device, the second insulating layer has two side-surfaces which are opposite to each other, and the covering layer contacts the two side-surfaces of the second insulating layer.

6. The electronic device as claimed in claim 1, wherein, in the cross-sectional view of the electronic device, the covering layer is greater than the second insulating layer in width.

7. The electronic device as claimed in claim 1, wherein the plurality of semiconductor elements comprise at least one of light emitting elements, integrated circuit chips, and passive components.

8. The electronic device as claimed in claim 7, further comprising a shielding layer disposed between the covering layer and the second insulating layer, wherein the shielding layer has a plurality of through-holes, and at least one of the plurality of semiconductor elements is disposed in one of the plurality of through-holes.

9. The electronic device as claimed in claim 8, further comprising an adhesive layer disposed between the covering layer and the shielding layer.

10. The electronic device as claimed in claim 9, wherein, in the cross-sectional view of the electronic device, the second insulating layer has two side-surfaces which are opposite to each other, the shielding layer has two outside-surfaces, and the adhesive layer contacts the two side-surfaces of the second insulating layer and the two outside-surfaces of the shielding layer.

11. The electronic device as claimed in claim 8, wherein the covering layer is configured to encapsulate the shielding layer.

12. The electronic device as claimed in claim 11, wherein, in the cross-sectional view of the electronic device, the second insulating layer has two side-surfaces which are opposite to each other, the shielding layer has two outside-surfaces, and the covering layer contacts the two side-surfaces of the second insulating layer and the two outside-surfaces of the shielding layer.

13. The electronic device as claimed in claim 1, wherein one of the plurality of semiconductor elements is different from another one of the plurality of semiconductor elements in function.

14. A method for manufacturing an electronic device, comprising
providing a substrate;
forming a first insulating layer on the substrate;
patterning the first insulating layer to form a first through-hole, wherein in a cross-sectional view of the electronic device, the first insulating layer has a side-surface corresponding to the first through-hole;
forming a second insulating layer on the first insulating layer, wherein the second insulating layer contacts the side-surface of the first insulating layer;
forming a conductive layer on the second insulating layer;
arranging a plurality of semiconductor elements on and electrically connected to the conductive layer; and
arranging a covering layer on the plurality of semiconductor elements.

15. The method as claimed in claim 14, further comprising:
patterning the second insulating layer to form a second through-hole, wherein, in the cross-sectional view of the electronic device, the second insulating layer has a side-surface corresponding to the second through-hole.

16. The method as claimed in claim 15, wherein the covering layer contacts the side-surface of the second insulating layer.

17. The method as claimed in claim 14, further comprising:
removing the substrate after arranging the covering layer on the plurality of semiconductor elements; and
cutting the covering layer.

18. The method as claimed in claim 14, further comprising:
forming an adhesive layer on the covering layer before arranging the covering layer on the plurality of semiconductor elements.

19. The method as claimed in claim 18, further comprising:
removing the substrate after arranging the covering layer on the plurality of semiconductor elements; and
cutting the covering layer.

20. The method as claimed in claim 19, further comprising:
patterning the adhesive layer to form a third through-hole before cutting the covering layer.
